(19) United States
(12) Patent Application Publication
(10) Pub. No.: US 2025/0085631 A1
(43) Pub. Date: Mar. 13, 2025

(54) PHOTORESIST UNDERLAYER MATERIALS AND ASSOCIATED METHODS

(71) Applicant: Taiwan Semiconductor Manufacturing Company, Ltd., Hsinchu (TW)

(72) Inventors: Yu-Chung SU, Hsinchu City (TW); Ching-Yu CHANG, Yilang County (TW); Yen-Yu KUO, New Taipei City (TW)

(21) Appl. No.: 18/404,434

(22) Filed: Jan. 4, 2024

Related U.S. Application Data
(60) Provisional application No. 63/582,403, filed on Sep. 13, 2023.

(51) Int. Cl. G03F 7/039; G03F 7/09; G03F 7/11; G03F 7/20; G03F 7/38; H01L 21/027

(52) U.S. Cl. CPC G03F 7/039; G03F 7/094; G03F 7/11; G03F 7/2004; G03F 7/2059; G03F 7/38; H01L 21/0275; H01L 21/0279

(57) ABSTRACT

A semiconductor device may be manufactured using a multiple-layer photoresist that is formed of one or more materials that reduce the likelihood and/or amount of residual material retained in the multiple-layer photoresist. A photoresist underlayer of the multiple-layer photoresist includes a polymer having a highly uniform distribution of polar group monomers. Additionally and/or alternatively, the photoresist underlayer includes a polymer that includes a main chain and a plurality of side chains coupled with the main chain. The side chains include an acid generator component. Since the acid generator component is coupled with the main chain of the polymer by the side chains as opposed to uncontrollably diffusing into the photoresist layer, the acid generated by the acid generator component upon exposure to radiation collects under the bottom of the photoresist layer in a uniform manner and enables the bottommost portions of the photoresist layer to be developed and removed.

### CROSS-REFERENCE TO RELATED APPLICATION

This patent application claims priority to U.S. Provisional Patent Application No. 63/582,403, filed on Sep. 13, 2023, and entitled “PHOTORESIST UNDERLAYER MATERIALS AND ASSOCIATED METHODS.” The disclosure of the prior application is considered part of and is incorporated by reference into this patent application.

### BACKGROUND

As semiconductor device sizes continue to shrink, some lithography technologies suffer from optical restrictions, which leads to resolution issues and reduced lithography performance. In comparison, extreme ultraviolet (EUV) lithography can achieve much smaller semiconductor device sizes and/or feature sizes through the use of reflective optics and radiation wavelengths of approximately 13.5 nanometers or less.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example implementation of an exposure tool described herein.

FIGS. 3A-3F are diagrams of an example implementation of forming a multiple-layer photoresist described herein.

FIGS. 4A-4C are diagrams of an example implementation of exposing a multiple-layer photoresist described herein to radiation to form a pattern in the multiple-layer photoresist.

FIGS. 5A-5C are diagrams of an example implementation of developing a pattern formed in a photoresist layer of a multiple-layer photoresist described herein.

FIGS. 6A and 6B are diagrams of examples of materials that may be used for R1 components and crosslinking group components described herein.

FIGS. 7A-7C are diagrams of examples of materials that may be used for acid generator components described herein.

FIGS. 8A-8C are diagrams of an example implementation of a multiple-layer photoresist described herein.

FIG. 9 is a diagram of an example implementation of a photoresist underlayer described herein.

FIG. 10 is a diagram of an example implementation of a photoresist underlayer described herein.

FIG. 11 is a diagram of an example implementation of a photoresist underlayer described herein.

FIG. 12 is a diagram of example components of a device described herein.

FIG. 13 is a flowchart of an example process associated with forming a multiple-layer photoresist on a semiconductor substrate described herein.

FIG. 14 is a flowchart of an example process associated with forming a multiple-layer photoresist on a semiconductor substrate described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One of the issues with extreme ultraviolet (EUV) lithography is that EUV radiation is highly absorbed by most matter due to the short wavelength of EUV radiation. As a result, only a small fraction of EUV radiation that is generated by an EUV source is finally available at a substrate that is to be patterned. Increasing the exposure dosage of the EUV radiation may result in reduced line width roughness (LWR) and/or reduced local critical dimension uniformity (LCDU) in features that are formed on the substrate. As a result, semiconductor manufacturers may be unable to simply increase the exposure dosage for their EUV lithography processes due to stringent optimized exposure dosage (Eₒₚ) parameters.

Multiple-layer photoresists may increase sensitivity to incident light in the EUV wavelength range. However, some drawbacks exist for multiple-layer photoresists. For example, a multiple-layer photoresist may include one or more photoresist underlayers and a photoresist layer on the one or more photoresist underlayers. A photoresist underlayer may include polar groups to promote adhesion with the photoresist layer, and the photoresist underlayer may include a non-uniform distribution of polar groups (e.g., hydroxyl groups). Regions of high concentration of the polar groups may more readily absorb and aggregate a photo-decomposable base (PDB) material in the photoresist layer, resulting in regions of high concentration of PDB material in the photoresist layer. The high concentration of PDB material may prevent these regions of the photoresist layer from being fully exposed, developed, and removed, which may result in residual material being retained in these regions (referred to as bottom scum or photoresist scum). The residual material may reduce the effectiveness of a subsequent semiconductor processing operation using the multiple-layer photoresist (e.g., may result in reduced etch depth in an etch operation, may result in reduced ion implantation coverage). This may increase the likelihood of defect formation for semiconductor devices on a semiconductor wafer on which the photoresist is formed.

As another example, a photoresist underlayer may include an acid generating component (e.g., a photo acid generator (PAG), a thermal acid generator (TAG)) that diffuses into the photoresist layer and generates an acid upon exposure to EUV radiation. The acid acts as a catalyst for causing a chemical reaction in the photoresist layer. The chemical reaction modifies (e.g., increases, decreases) the solubility of exposed portions of the photoresist layer, thereby enabling the multiple-layer photoresist to be patterned based on exposure to EUV radiation. However, the acid generating components may diffuse into the photoresist layer in a non-uniform manner, which may prevent or reduce the likelihood of residual material in the photoresist layer from being removed. Non-uniform distribution of the acid generating component may result in regions of low concentration of acid at the bottom of the photoresist layer. Thus, the amount of acid generated at the bottom of the photoresist layer may be insufficient to develop and remove the full thickness of the photoresist layer.

In some implementations described herein, a semiconductor device may be manufactured using a multiple-layer photoresist. The multiple-layer photoresist is formed of one or more materials that reduce the likelihood of and/or the amount of residual material retained in a photoresist layer of the multiple-layer photoresist after the photoresist layer is exposed to EUV radiation and developed. In some implementations, a photoresist underlayer of the multiple-layer photoresist includes a polymer having a highly uniform distribution of polar group monomers.

In some implementations, a photoresist underlayer of the multiple-layer photoresist includes a polymer that includes a main chain and a plurality of side chains coupled with the main chain. The side chains include an acid generator component such as a PAG and/or a TAG, among other examples. Since the acid generator component is coupled with the main chain of the polymer by the side chains as opposed to uncontrollably diffusing into the photoresist layer, the acid generated by the acid generator component upon exposure to EUV radiation collects under the bottom of the photoresist layer in a uniform manner and enables the bottommost portions of the photoresist layer to be developed and removed. This reduces the likelihood that residual photoresist material is retained in the photoresist layer, which may reduce LWR and/or may decrease LCDU in features that are formed in the semiconductor device using the multiple-layer photoresist. The reduced LWR and/or the decreased LCDU may enable the features to be formed to smaller dimensions and/or increased uniformity, thereby increasing yield of semiconductor structures formed on the semiconductor device.

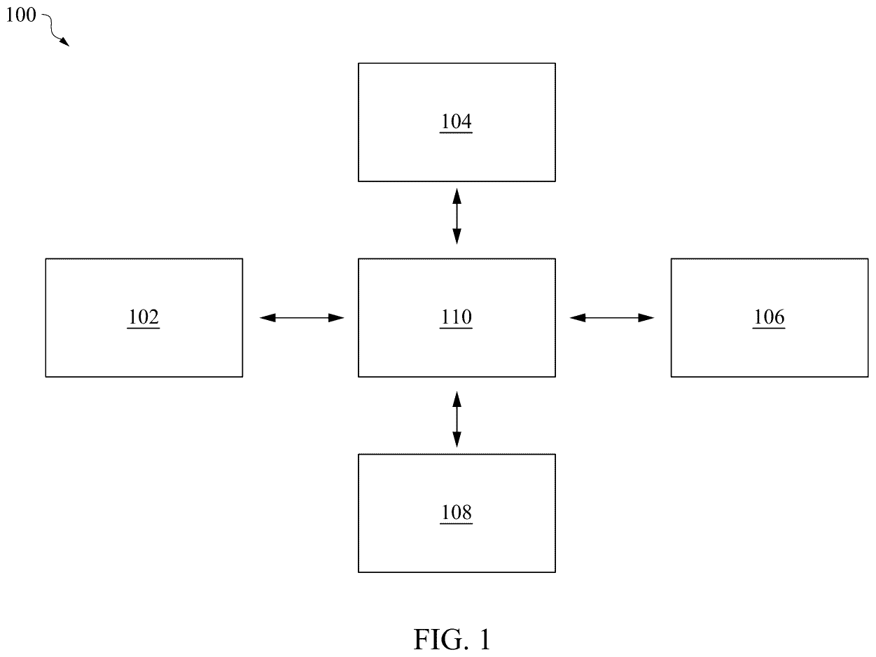

FIG. 1 is a diagram of an example environment 100 in which systems and/or methods described herein may be implemented. As shown in FIG. 1, the example environment 100 may include a plurality of semiconductor processing tools 102-108 and a wafer/die transport tool 110. The plurality of semiconductor processing tools 102-108 may include a deposition tool 102, an exposure tool 104, a developer tool 106, an etch tool 108, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

Wafer/die transport tool 110 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-108, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 110 may be a programmed device that is configured to travel a particular path and/or may operate semi-autonomously or autonomously. In some implementations, the example environment 100 includes a plurality of wafer/die transport tools 110.

For example, the wafer/die transport tool 110 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 110 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 110 is configured to transport substrates and/or semiconductor devices between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-108 and/or the wafer/die transport tool 110 may be used to perform one or more semiconductor processing operations described herein. For example, one or more of the semiconductor processing tools 102-108 and/or the wafer/die transport tool 110 may be used to form a photoresist underlayer over a substrate, where the photoresist underlayer comprises a polymer and an acid generator component; perform a treatment operation on the photoresist underlayer, where a polar group distribution uniformity across a top surface of the photoresist underlayer after the treatment operation is greater than the polar group distribution uniformity across the top surface of the photoresist underlayer prior to the treatment operation; form, after the treatment operation, a photoresist layer over the photoresist underlayer; expose the photoresist layer to radiation to form a pattern in the photoresist layer, where the acid generator component in the photoresist underlayer reacts with the radiation to form an acid that results in formation of the pattern in the photoresist layer; and develop the pattern in the photoresist layer.

As another example, one or more of the semiconductor processing tools 102-108 and/or the wafer/die transport tool 110 may form a photoresist underlayer over a substrate, where the photoresist underlayer includes a main polymer chain, a plurality of acid generator component side chains coupled with the main polymer chain, and an acid generator component coupled with the plurality of acid generator component side chains; form a photoresist layer over the photoresist underlayer; expose the photoresist layer to radiation to form a pattern in the photoresist layer, where the acid generator component in the photoresist underlayer reacts with the radiation to form an acid that results in formation of the pattern in the photoresist layer; and develop the pattern in the photoresist layer.

As another example, one or more of the semiconductor processing tools 102-108 and/or the wafer/die transport tool 110 may form a photoresist underlayer over a substrate, where the photoresist underlayer includes a main polymer chain, a plurality of acid generator component side chains coupled with the main polymer chain, and an acid generator component coupled with the plurality of acid generator component side chains; perform a treatment operation on the photoresist underlayer, where a polar group distribution uniformity across a top surface of the photoresist underlayer after the treatment operation is greater than the polar group distribution uniformity across the top surface of the photoresist underlayer prior to the treatment operation; form, after the treatment operation, a photoresist layer over the photoresist underlayer; expose the photoresist layer to radiation to form a pattern in the photoresist layer, where the acid generator component in the photoresist underlayer reacts with the radiation to form an acid that results in formation of the pattern in the photoresist layer; and develop the pattern in the photoresist layer.

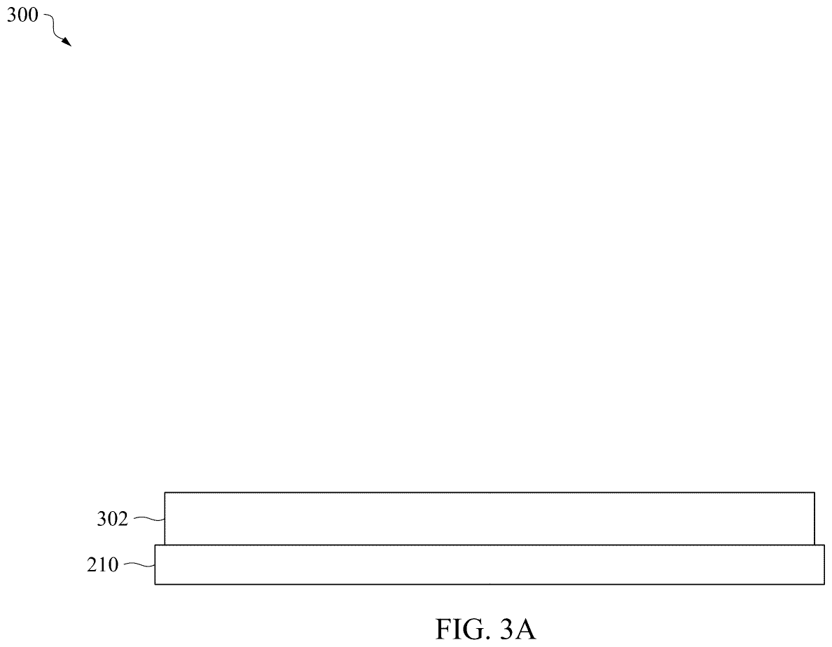

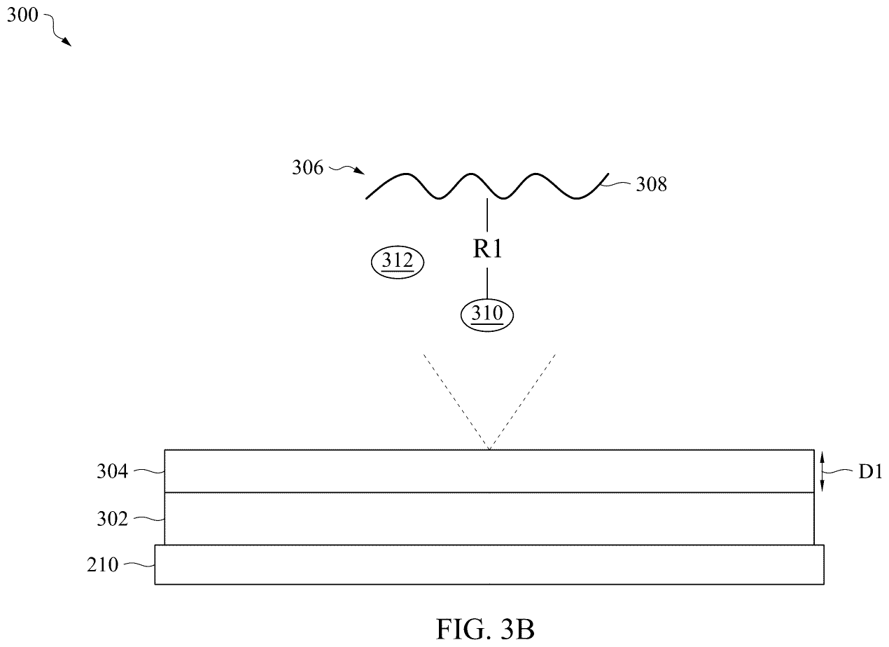

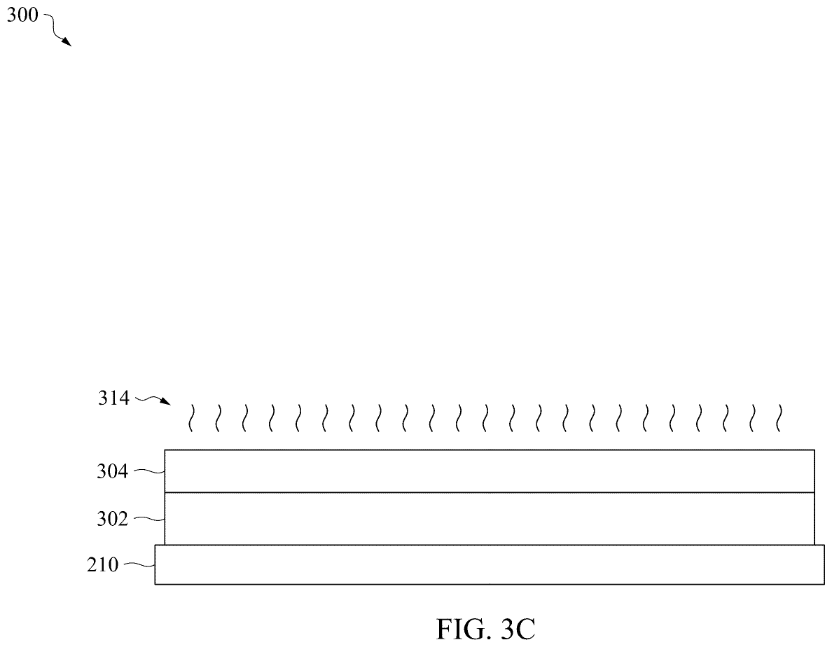

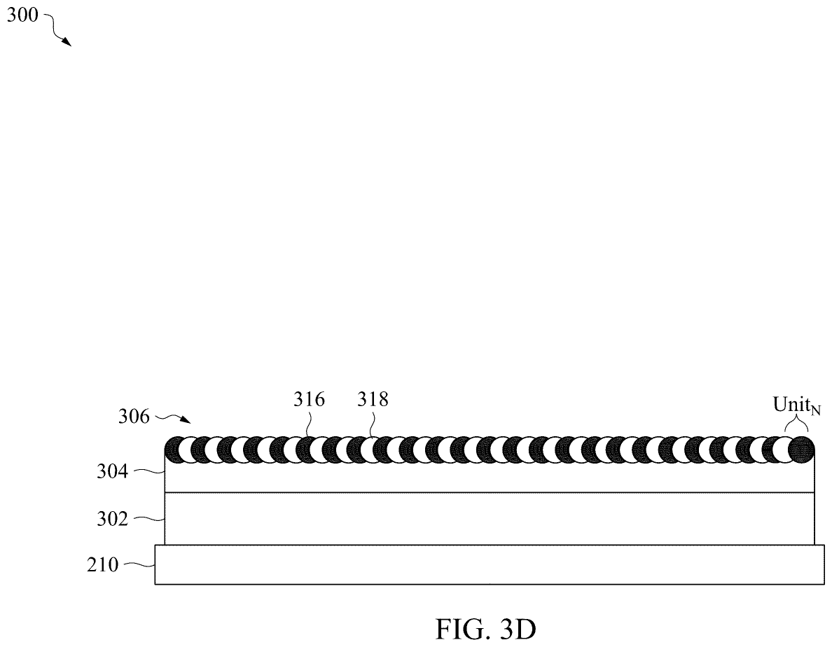

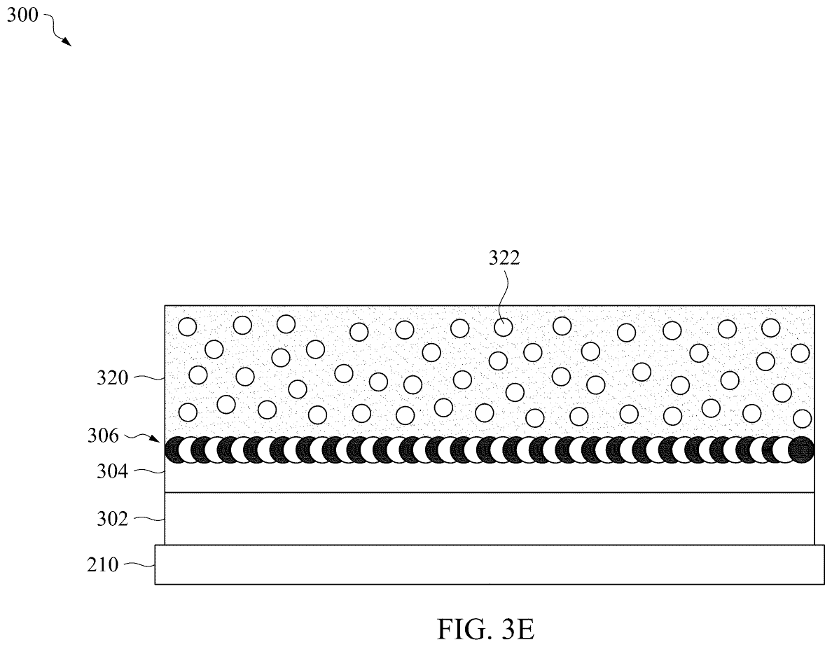

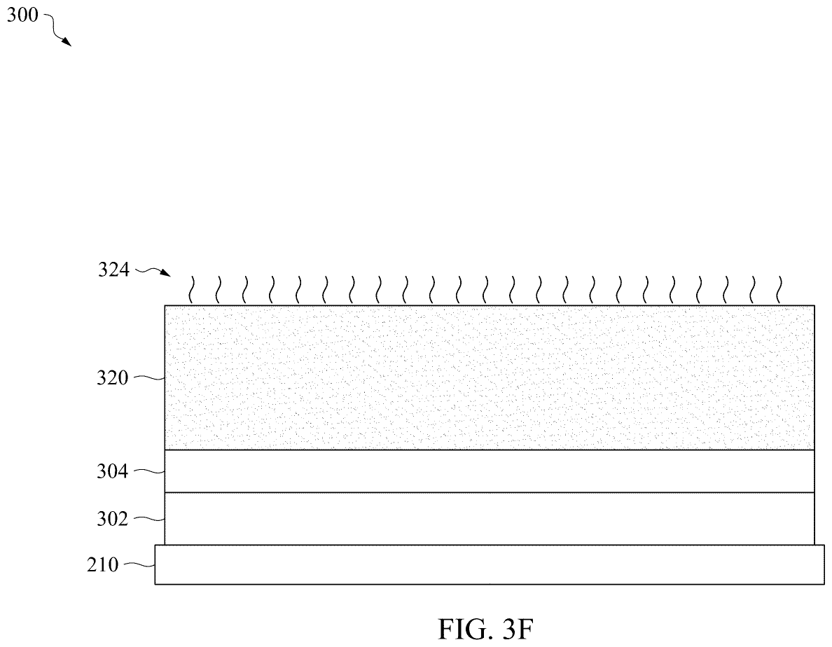

In some implementations, one or more of the semiconductor processing tools 102-108 and/or the wafer/die transport tool 110 may be used to perform one or more semiconductor processing operations described in connection with FIGS. 3A-3F, 4A-4C, 5A, 5B, 8A-8C, 9-11, and/or 13-15, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

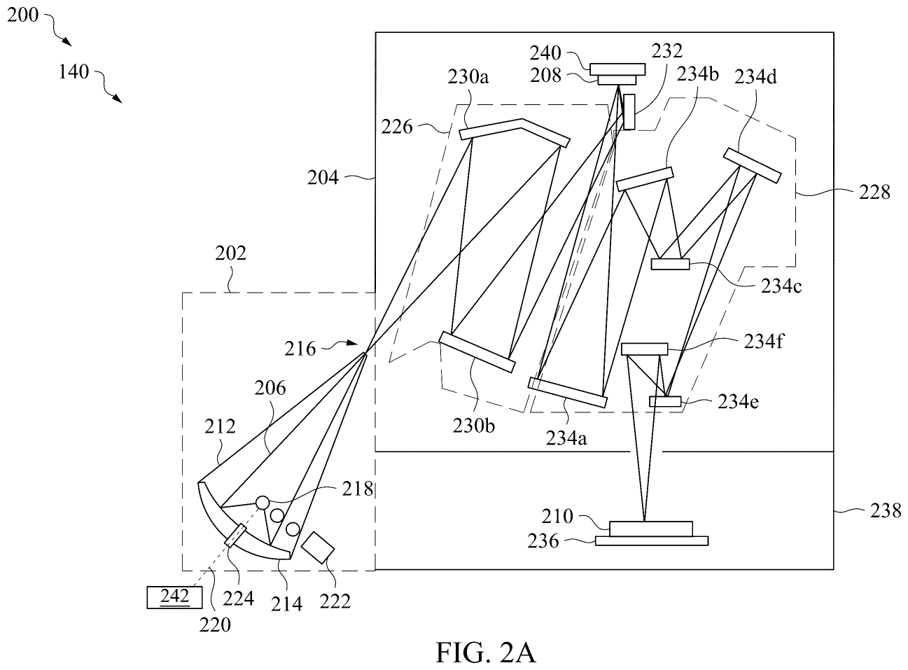

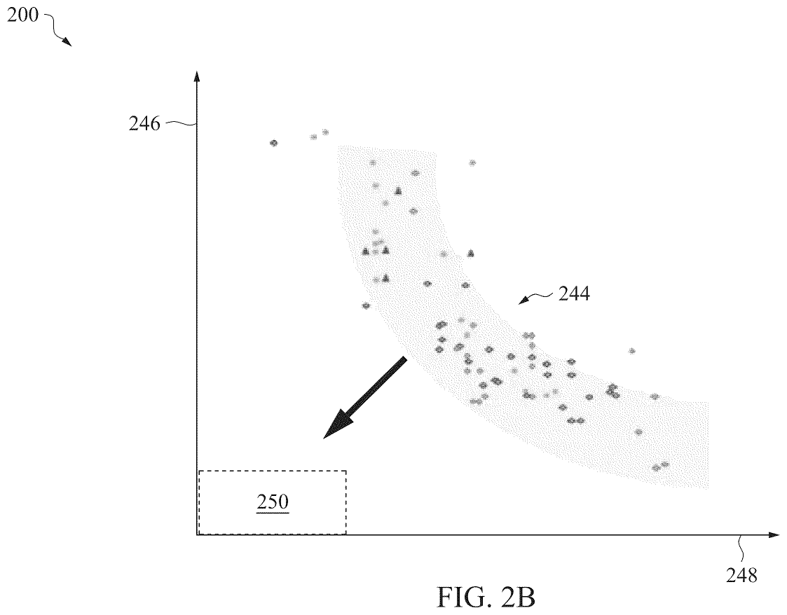

FIGS. 2A and 2B are diagrams of an example implementation 200 of an exposure tool 104 described herein. The exposure tool 104 includes an EUV lithography system or another type of lithography system that is configured to transfer a pattern to a semiconductor substrate using mirror-based optics. The exposure tool 104 may be configured for use in a semiconductor processing environment such as a semiconductor foundry or a semiconductor fabrication facility.

As shown in FIG. 2A, the exposure tool 104 includes the radiation source 202 and an exposure system 204. The radiation source 202 (e.g., an EUV radiation source or another type of radiation source) is configured to generate radiation 206 such as EUV radiation and/or another type of electromagnetic radiation (e.g., light). The exposure system 204 (e.g., an EUV scanner or another type of exposure tool) is configured to focus the radiation 206 onto a reflective reticle 208 (or a photomask) such that a pattern is transferred from the reticle 208 onto a semiconductor substrate 210 using the radiation 206.

The radiation source 202 includes a vessel 212 and a collector 214 in the vessel 212. The collector 214, includes a curved mirror that is configured to collect the radiation 206 generated by the radiation source 202 and to focus the radiation 206 toward an intermediate focus 216. The radiation 206 is produced from a plasma that is generated from droplets 218 (e.g., tin (Sn) droplets or another type of droplets) being exposed to a laser beam 220. The droplets 218 are provided across the front of the collector 214 by a droplet generator (DG) head 222. The DG head 222 is pressurized to provide a fine and controlled output of the droplets 218.

A laser source, such as a pulse carbon dioxide (CO₂) laser, generates the laser beam 220. The laser beam 220 is provided (e.g., by a beam delivery system to a focus lens) such that the laser beam 220 is focused through a window 224 of the collector 214. The laser beam 220 is focused onto the droplets 218 which generates the plasma. The plasma produces a plasma emission, some of which is the radiation 206. The laser beam 220 is pulsed at a timing that is synchronized with the flow of the droplets 218 from the DG head 222.

The exposure system 204 includes an illuminator 226 and a projection optics box (POB) 228. The illuminator 226 includes a plurality of reflective mirrors that are configured to focus and/or direct the radiation 206 onto the reticle 208 so as to illuminate the pattern on the reticle 208. The plurality of mirrors include, for example, a mirror 230a and a mirror 230b. The mirror 230a includes a field facet mirror (FFM) or another type of mirror that includes a plurality of field facets. The mirror 230b includes a pupil facet mirror (PFM) or another type of mirror that also includes a plurality of pupil facets. The facets of the mirrors 230a and 230b are arranged to focus, polarize, and/or otherwise tune the radiation 206 from the radiation source 202 to increase the uniformity of the radiation 206 and/or to increase particular types of radiation components (e.g., transverse electric (TE) polarized radiation, transverse magnetic (TM) polarized radiation). Another mirror 232 (e.g., a relay mirror) is included to direct radiation 206 from the illuminator 226 onto the reticle 208.

The projection optics box 228 includes a plurality of mirrors that are configured to project the radiation 206 onto the semiconductor substrate 210 after the radiation 206 is modified based on the pattern of the reticle 208. The plurality of reflective mirrors include, for example, mirrors 234a-234f. In some implementations, the mirrors 234a-234f are configured to focus or reduce the radiation 206 into an exposure field, which may include one or more die areas on the semiconductor substrate 210.

The exposure system 204 includes a wafer stage 236 (e.g., a substrate stage) configured to support the semiconductor substrate 210. Moreover, the wafer stage 236 is configured to move (or step) the semiconductor substrate 210 through a plurality of exposure fields as the radiation 206 transfers the pattern from the reticle 208 onto the semiconductor substrate 210. The wafer stage 236 is included in a bottom module 238 of the exposure system 204. The bottom module 238 includes a removable subsystem of the exposure system 204. The bottom module 238 may slide out of the exposure tool 104 and/or otherwise may be removed from the exposure system 204 to enable cleaning and inspection of the wafer stage 236 and/or the components of the wafer stage 236. The bottom module 238 isolates the wafer stage 236 from other areas in the exposure system 204 to reduce and/or minimize contamination of the semiconductor substrate 210. Moreover, the bottom module 238 may provide physical isolation for the wafer stage 236 by reducing the transfer of vibrations (e.g., vibrations in the semiconductor processing environment in which the exposure tool 104 is located, vibrations in the exposure tool 104 during operation of the exposure tool 104) to the wafer stage 236 and, therefore, the semiconductor substrate 210. This reduces movement and/or disturbance of the semiconductor substrate 210, which reduces the likelihood that the vibrations may cause a pattern misalignment.

The exposure system 204 also includes a reticle stage 240 that configured to support and/or secure the reticle 208. Moreover, the reticle stage 240 is configured to move or slide the reticle through the radiation 206 such that the reticle 208 is scanned by the radiation 206. In this way, a pattern that is larger than the field or beam of the radiation 206 may be transferred to the semiconductor substrate 210.

The exposure tool 104 includes a laser source 242. The laser source 242 is configured to generate the laser beam 220. The laser source 242 may include a CO₂-based laser source or another type of laser source. Due to the wavelength of the laser beams generated by a CO₂-based laser source in an infrared (IR) region, the laser beams may be highly absorbed by tin, which enables the CO₂-based laser source to achieve high power and energy for pumping tin-based plasma. In some implementations, the laser beam 220 includes a plurality of types of laser beams that the laser source 242 generates using a multi-pulse technique (or a multi-stage pumping technique), in which the laser source 242 generates a pre-pulse laser beam and main-pulse laser beam to achieve greater heating efficiency of tin (Sn)-based plasma to increase conversion efficiency.

In an example exposure operation (e.g., an EUV exposure operation), the DG head 222 provides the stream of the droplets 218 across the front of the collector 214. The laser beam 220 contacts the droplets 218, which causes a plasma to be generated. The laser source 242 generates and provides a pre-pulse laser beam toward a target material droplet in the stream of the droplets 218, and the pre-pulse laser beam is absorbed by the target material droplet. This transforms the target material droplet into disc shape or a mist. Subsequently, the laser source 242 provides a main-pulse laser beam with large intensity and energy toward the disc-shaped target material or target material mist. Here, the atoms of the target material are neutralized, and ions are generated through thermal flux and shock wave. The main-pulse laser beam pumps ions to a higher charge state, which causes the ions to radiate the radiation 206 (e.g., EUV light).

The radiation 206 is collected by the collector 214 and directed out of the vessel 212 and into the exposure system 204 toward the mirror 230a of the illuminator 226. The mirror 230a reflects the radiation 206 onto the mirror 230b, which reflects the radiation 206 onto the mirror 232 toward the reticle 208. The radiation 206 is modified by the pattern in the reticle 208. In other words, the radiation 206 reflects off of the reticle 208 based on the pattern of the reticle 208. The reflective reticle 208 directs the radiation 206 toward the mirror 234a in the projection optics box 228, which reflects the radiation 206 onto the mirror 234b. The radiation 206 continues to be reflected and reduced in the projection optics box 228 by the mirrors 234c-234f. The mirror 234f reflects the radiation 206 onto the semiconductor substrate 210 such that the pattern of the reticle 208 is transferred to the semiconductor substrate 210. The above-described exposure operation is an example, and the exposure tool 104 may operate according to other EUV techniques and radiation paths that include a greater quantity of mirrors, a lesser quantity of mirrors, and/or a different configuration of mirrors.

FIG. 2B illustrates an operating range 244 of the exposure tool 104 in which LWR 246 is dependent on exposure energy dose (Eₒₚ) 248 of the radiation 206. Absorption of EUV photons of the radiation 206 into a photoresist may be low because EUV photons are more readily absorbed by the components of the exposure tool 104 described in FIG. 2A relative to deep UV radiation. Thus, fewer EUV photons reach the photoresist on the semiconductor substrate 210 than for deep UV radiation, resulting in low LWR 246 for a pattern formed in the photoresist on the semiconductor substrate 210. The Eₒₚ 248 of the exposure tool 104 may be increased, thereby increasing the amount of EUV photons that eventually make it into the photoresist on the semiconductor substrate 210. While this reduces LWR 246 in the pattern that is formed in the photoresist, increasing the Eₒₚ 248 increases the power consumption of the exposure tool 104 and decreases the operating efficiency of the exposure tool 104. On the other hand, power consumption can be reduced by reducing the Eₒₚ 248, at the expense of reduced EUV photon absorption and increased LWR 246.

The photoresist materials and techniques described herein enable a low LWR 246 to be achieved for a pattern formed in the photoresist on the semiconductor substrate 210 with a relatively low Eₒₚ 248 (indicated in a target area 250 in FIG. 2B). The photoresist materials described herein include chemically amplified reaction (CAR) photoresist materials. As described herein, the photoresist materials may be used to form a multiple-layer photoresist that includes a photoresist underlayer. The photoresist underlayer may include a polymer having a highly uniform distribution of polar group monomers. Additionally and/or alternatively, the photoresist underlayer includes a polymer that includes a main chain and a plurality of side chains coupled with the main chain. The side chains include an acid generator component. Since the acid generator component is coupled with the main chain of the polymer by the side chains as opposed to uncontrollably diffusing into the photoresist layer, the acid generated by the acid generator component upon exposure to the radiation 206 collects under the bottom of the photoresist layer in a uniform manner and enables the bottommost portions of the photoresist layer to be developed and removed. This reduces the likelihood that residual photoresist material is retained in the photoresist layer, which may reduce LWR 246 and/or may decrease LCDU in features that are formed in the semiconductor device using the multiple-layer photoresist. The reduced LWR 246 and/or the decreased LCDU may enable the features to be formed to smaller dimensions and/or increased uniformity, thereby increasing yield of semiconductor structures formed on the semiconductor substrate 210.

As indicated above, FIGS. 2A and 2B are provided as an example. Other examples may differ from what is described with regard to FIGS. 2A and 2B.

FIGS. 3A-3F are diagrams of an example implementation 300 of forming a multiple-layer photoresist described herein. The example implementation 300 includes an example of forming the multiple-layer photoresist over a layer 302 on a semiconductor substrate 210 that is to be patterned using the multiple-layer photoresist. For example, the layer 302 may be etched using an etch tool 108 based on a pattern that is formed in the multiple-layer photoresist. Additionally and/or alternatively, the semiconductor substrate 210 may be processed based on a pattern formed in the multiple-layer photoresist.

Turning to FIG. 3A, the semiconductor substrate 210 may be positioned in a processing chamber of a deposition tool 102. The semiconductor substrate 210 includes a semiconductor die substrate, a semiconductor wafer, or another type of substrate in and/or on which semiconductor devices may be formed. In some implementations, the semiconductor substrate 210 is formed of silicon (Si), a material including silicon, a III-V compound semiconductor material such as gallium arsenide (GaAs), a silicon on insulator (SOI), or another type of semiconductor material.

The deposition tool 102 may be used to form the layer 302 over and/or on the semiconductor substrate 210. The layer 302 may be etched to form various types of semiconductor devices, openings, trenches, vias, interconnects, contacts, and/or other types of semiconductor structures. The layer 302 may include a dielectric layer, a metallization layer, a hard mask layer, and/or another type of semiconductor layer.

As shown in FIG. 3B, a photoresist underlayer 304 of the multiple-layer photoresist is formed over the semiconductor substrate 210 (e.g., over the layer 302 on the semiconductor substrate 210). A deposition tool 102 may be used to deposit the photoresist underlayer 304 using various PVD techniques, CVD techniques and/or ALD techniques, such as spin-coating, sputtering, PECVD, HDP-CVD, SACVD, and/or PEALD, among other examples. The photoresist underlayer 304 includes a middle layer (ML), a bottom layer (BL), a bottom antireflective coating (BARC) layer, and/or another type of underlayer.

In some implementations, the photoresist underlayer 304 is formed to a thickness (indicated in FIG. 3B as dimension D1) that is included in a range of approximately 5 angstroms to approximately 500 angstroms to satisfy one or more etching parameters for etching the layer 302 (e.g., such as a target depth and/or a target width for the trenches or openings that are to be etched into the layer 302). If the photoresist underlayer 304 is formed to a thickness that is outside this range, the photoresist underlayer may not provide sufficient reactant chemicals to other layers of the multiple-layer photoresist to permit patterning of the multiple-layer photoresist. However, other values for the thickness of the photoresist underlayer 304, and ranges other than approximately 5 angstroms to approximately 500 angstroms, are within the scope of the present disclosure.

As further shown in FIG. 3B, the photoresist underlayer 304 includes a polymer material 306. The polymer material 306 includes a main polymer chain 308, a crosslinking group component 310 coupled to the main polymer chain 308 by an R1 component, and an acid generator component 312. The polymer chain 308 may include an oligomer, a co-polymer, and/or another type of polymer that includes polar groups (e.g., hydroxyl groups and/or another type of polar groups). The polymer chain 308 may include other elements, such as carbon (C), silicon (Si), and/or another element, among other examples. In some implementations, the polymer chain 308 includes phenol formaldehyde resin, a poly(norbornene)-co-malaic anhydride (COMA) polymer, a poly(4-hydroxystyrene) (PHS) polymer, a phenol-formaldehyde (hakelite) polymer, a polyethylene (PE) polymer, a polypropylene (PP) polymer, a polycarbonate polymer, a polyester polymer, and/or or an acrylate-based polymer such as a poly (methyl methacrylate) (PMMA) polymer or poly (methacrylic acid) (PMAA), among other examples. In some implementations, the polymer chain 308 is cyclic or non-cyclic, saturated or unsaturated, substituted or unsubstituted, and/or branched or unbranched. In some implementations, the polymer chain 308 includes a hydrocarbon group (e.g., alkyl group, alkenyl group) having a quantity of carbon atoms in a range of 2 to 18 (C2-C18). If substituted, the C2-C18 hydrocarbon group can be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, epoxy, and/or aryl (e.g., phenyl), among other examples.

The R1 component may include an acid labile group (ALG) component, a dissolution inhibitor, and/or another type of component linking the crosslinking group component 310 to the main polymer chain 308. In some implementations, the R1 component includes tert-butoxycarbonyl (tBOC). In some implementations, the R1 component includes methylcyclopentyl (MCP) bonded to a carboxyl group of the main polymer chain 308. In some implementations, the R1 component includes ethylcyclopentyl bonded to a carboxyl group of the main polymer chain 308. In some implementations, the R1 is cyclic or non-cyclic, saturated or unsaturated, substituted or unsubstituted, and/or branched or unbranched. In some implementations, the R1 includes a hydrocarbon group (e.g., alkyl group, alkenyl group) having a quantity of carbon atoms in a range of 2 to 18 (C2-C18). If substituted, the C2-C18 hydrocarbon group can be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, epoxy, and/or aryl (e.g., phenyl), among other examples.

The crosslinking group component 310 may include a cross-linkable functional group, such as alkene, alkyne, triazene, or other suitable functional group. In some implementations, the crosslinking group component 310 is cyclic or non-cyclic, saturated or unsaturated, substituted or unsubstituted, and/or branched or unbranched. In some implementations, the crosslinking group component 310 includes a hydrocarbon group (e.g., alkyl group, alkenyl group) having a quantity of carbon atoms in a range of 2 to 18 (C2-C18). If substituted, the C2-C18 hydrocarbon group can be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, epoxy, and/or aryl (e.g., phenyl), among other examples.

The crosslinking group component 310 may be approximately 10% to approximately 99% of the atomic weight of the polymer material 306. In some implementations, an additive is included in the photoresist underlayer 304 to trigger a cross-linking reaction of the crosslinking group component 310. The additive may be approximately 0.1% to approximately 30% of the atomic weight of the crosslinking group component 310 included in the polymer material 306.

The acid generator component 312 may include a photo acid generator (PAG), a thermal acid generator (TAG), and/or another type of acid generator component that generates an acid based on absorbing radiation and/or heat. The acid generator component 312 may include a combination of one or more cations and one or more anions. The acid generator component 312 may be selected such that the acid generator component 312 diffuses by concentration gradient in the photoresist underlayer 304 after a treatment operation. The acid generator component 312 may be approximately 0.1% to approximately 30% of the atomic weight of the polymer material 306.

As shown in FIG. 3C, a treatment operation 314 is performed on the photoresist underlayer 304. The treatment operation 314 may be performed to remove a solvent from the photoresist underlayer 304 and/or to promote a uniform distribution of polar groups in the polymer material 306 across the photoresist underlayer 304. In some implementations, the treatment operation 314 results in the acid generator component 312 generating an acid. The treatment operation 314 may include a thermal treatment operation (e.g., a treatment operation in which the photoresist underlayer 304 is cured with applied heat), an ultraviolet (UV) treatment operation (e.g., a treatment operation in which the photoresist underlayer 304 is cured with UV radiation), an electron-beam (e-beam) treatment operation (e.g., a treatment operation in which the photoresist underlayer 304 is cured with e-beam radiation), and/or another type of treatment operation.

For a thermal treatment operation, the treatment operation 314 may be performed in a temperature range of approximately 100 degrees Celsius to approximately 400 degrees Celsius to achieve sufficient cross-linking in the photoresist underlayer 304 without causing damage to the photoresist underlayer 304. However, other values for the range are within the scope of the present disclosure.

As shown in FIG. 3D, the photoresist underlayer 304 may have a high uniformity of polar group distribution across a top surface of the photoresist underlayer 304 after the treatment operation 314. The polar group distribution uniformity across a top surface of the photoresist underlayer 304 after the treatment operation is greater than the polar group distribution uniformity across the top surface of the photoresist underlayer 304 prior to the treatment operation. The uniformity of the polar group distribution across the top surface of the photoresist underlayer 304 satisfies a uniformity threshold. The threshold may be included in a range of approximately 35% uniformity to approximately 100% uniformity such that the uniformity of the polar group distribution across the top surface of the photoresist underlayer 304 promotes a uniform distribution of a PDB component in a photoresist layer that is to be formed on the photoresist underlayer 304. In some implementations, the uniformity of the polar group distribution across the top surface of the photoresist underlayer 304 is greater than 45%. However, other values for uniformity of the polar group distribution across the top surface of the photoresist underlayer 304 are within the scope of the present disclosure.

The uniformity of the polar group distribution across the top surface of the photoresist underlayer 304 may be defined based on the distribution of monomers in the polymer material 306 across the top surface of the photoresist underlayer 304. For example, the polymer material 306 may include monomers 316 and 318, which may respectively be an oxygen (O) monomer and a hydrogen (H) monomer (thus forming a hydroxyl (OH) polar group). The distribution of co-monomers (e.g., the monomers 316 and 318) across the top surface of the photoresist underlayer 304 may satisfy the uniformity threshold. The distribution uniformity of the co-monomers (e.g., the monomers 316 and 318) may be determined as a number-average sequence length (NASL), which is the average number of monomers 316 and 318 across all blocks of a specific monomer in the polymer material 306. The NASL may be determined based on subunits in the polymer material 306, such as dimeric units (la) and (1b), and triad units (2a) and (2b) described below:

$${N}_{A} = \frac{{n}_{AA} + \frac{1}{2} {n}_{AB + BA}}{\frac{1}{2} {n}_{AB + BA}} \qquad ( 1 a )$$

$${N}_{B} = \frac{{n}_{BB} + \frac{1}{2} {n}_{AB + BA}}{\frac{1}{2} {n}_{AB + BA}} \qquad ( 1 b )$$

$${N}_{A} = \frac{{n}_{AAA} + {n}_{AAB + BAA} + {n}_{BAB}}{\frac{1}{2} {n}_{AAB + BAA} + {n}_{BAB}} \qquad ( 2 a )$$

$${N}_{B} = \frac{{n}_{BBB} + {n}_{BBA + ABB} + {n}_{ABA}}{\frac{1}{2} {n}_{BBA + ABB} + {n}_{BAB}} \qquad ( 2 b )$$

where various combinations of the monomers 316 and 318 are used to determine the distribution uniformity. n_{AA} may correspond to the quantity of occurrences of two adjacent monomers 316, n_{AB+BA} may correspond to the quantity of occurrences of a group of a monomers 316 and 318 adjacent to a group of monomers 318 and 316, n_{BB} may correspond to a quantity of occurrences of two adjacent monomers 318, n_{AAA} may correspond to the quantity of occurrences of three adjacent monomers 316, n_{BAB} may correspond to a quantity of occurrences of adjacent monomers 318, 316, and 318, n_{ABA} may correspond to a quantity of occurrences of adjacent monomers 316, 318, and 316, n_{AAB+BAA} may correspond to the quantity of occurrences of a group of a monomers 316, 316, and 318 adjacent to a group of monomers 318, 316, and 316, and n_{BBA+ABB} may correspond to the quantity of occurrences of a group of a monomers 318, 318, and 316 adjacent to a group of monomers 316, 318, and 318.

As further shown in FIG. 3D, in some implementations, a high distribution uniformity of the monomers 316 and 318 across the top surface of the photoresist underlayer 304 is defined as the monomers 316 and 318 being arranged in an alternating manner. For example, two adjacent monomers (regardless of whether the adjacent monomers are a monomer 316 or a monomer 318) may be referred to as a Unit_{N}. A Unit_{AB} may correspond to a Unit_{N} that specifically includes a monomer 316 and an adjacent monomer 318. In some implementations, the ratio of the quantity of Unit_{AB} to the quantity of Unit_{N} (e.g., quantity of Unit_{AB}/quantity of Unit_{N}) across the top surface of the photoresist underlayer 304 may correspond to the distribution uniformity of polar groups across the top surface of the photoresist underlayer 304.

As shown in FIG. 3E, a photoresist layer 320 is formed over and/or on the photoresist underlayer 304. A deposition tool 102 may be used to deposit the photoresist layer 320 using various PVD techniques, CVD techniques, and/or ALD techniques, such as spin-coating, sputtering, PECVD, HDP-CVD, SACVD, and/or PEALD, among other examples. The photoresist material may be mixed with a solvent, such as propylene glycol methyl ether acetate (PGMEA), propylene glycol monomethyl ether (PGME), 1-Ethoxy-2-propanol (PGEE), Gamma-Butyrolactone (GBL), cyclohexanone (CHN), ethyl lactate (EL), methanol, ethanol, propanol, n-butanol, acetone, dimethylformamide (DMF), isopropyl alcohol (IPA), tetrahydrofuran (THF), methyl isobutyl carbinol (MIBC), n-butyl acetate (nBA), 2-heptanone (MAK), and/or another photoresist solvent to facilitate the distribution of photoresist material across the semiconductor substrate 210 in a spin coating operation to form the photoresist layer 320.

As further shown in FIG. 3E, the high uniformity of the polar groups (e.g., the monomers 316 and 318) across the top surface of the photoresist underlayer 304 promotes uniform distribution of a PDB component 322 in the photoresist layer 320 and suppresses aggregation of the PDB component 322 at the bottom of the photoresist layer 320. If the distribution of the polar groups across the top surface of the photoresist underlayer 304 were not uniform, areas of high concentration of the PDB component 322 might otherwise occur in the photoresist layer 320. These areas of high concentration of the PDB component 322 might quench the generation of a photo acid in the photoresist layer 320 too quickly, resulting in underdeveloped portions of exposed photoresist layer 320, which would otherwise result in residual material (e.g., photoresist scum) remaining over the semiconductor substrate 210. Accordingly, the formation of the photoresist underlayer 304 such that the polymer material 306 has a high distribution uniformity of polar groups across the top surface of the photoresist underlayer 304 promotes full development of a pattern in the photoresist layer 320, which reduces the amount of residual material remaining over the semiconductor substrate 210, and reduces the likelihood of defect formation in structures formed in the layer 302 and/or in the semiconductor substrate 210 using the pattern.

As shown in FIG. 3F, a pre-exposure bake operation 324 may be performed on the photoresist layer 320. The pre-exposure bake (or soft bake) operation 324 may include a baking operation that is performed prior to exposure of a photoresist layer 320 on the semiconductor substrate 210 to radiation 206 using the exposure tool 104. The pre-exposure bake operation 324 may be performed to evaporate a solvent that is mixed with the photoresist material. The pre-exposure bake operation 324 may promote the solidification of the photoresist material into the photoresist layer 320.

The pre-exposure bake operation 324 is performed for a time duration that may be in a range of approximately 30 seconds to approximately 600 seconds to ensure that the photoresist layer 320 is fully baked (and the solvent is fully removed) without unduly reducing throughput of photoresist pattern formation. However, other values for the time duration are within the scope of the present disclosure. In some implementations, the pre-exposure bake operation 324 may be performed at a temperature that is in a range of approximately 65 degrees Celsius to approximately 200 degrees Celsius to ensure that the solvent is removed from the photoresist material while reducing and/or minimizing metal cluster cross-linking in the photoresist layer 320 (which might lead to a reduction in resolution between exposed and unexposed portions of the photoresist layer 320). However, other values for the temperature are within the scope of the present disclosure.

As indicated above, FIGS. 3A-3F are provided as an example. Other examples may differ from what is described with regard to FIGS. 3A-3F.

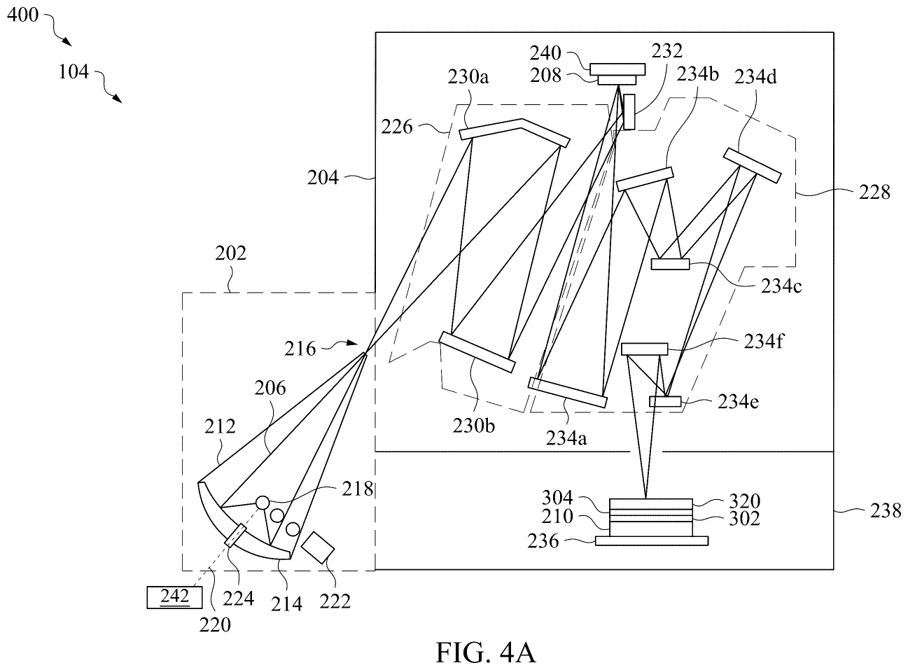

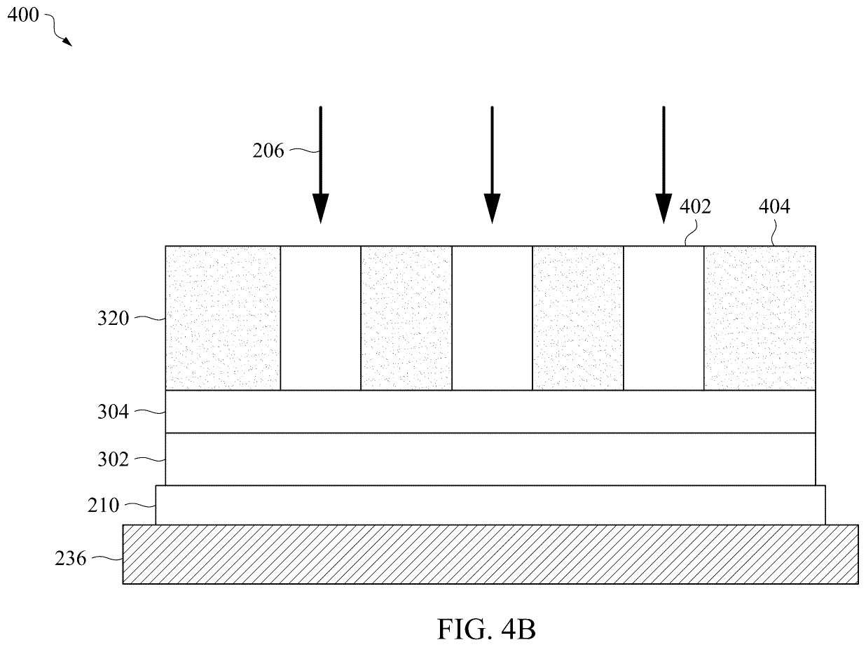

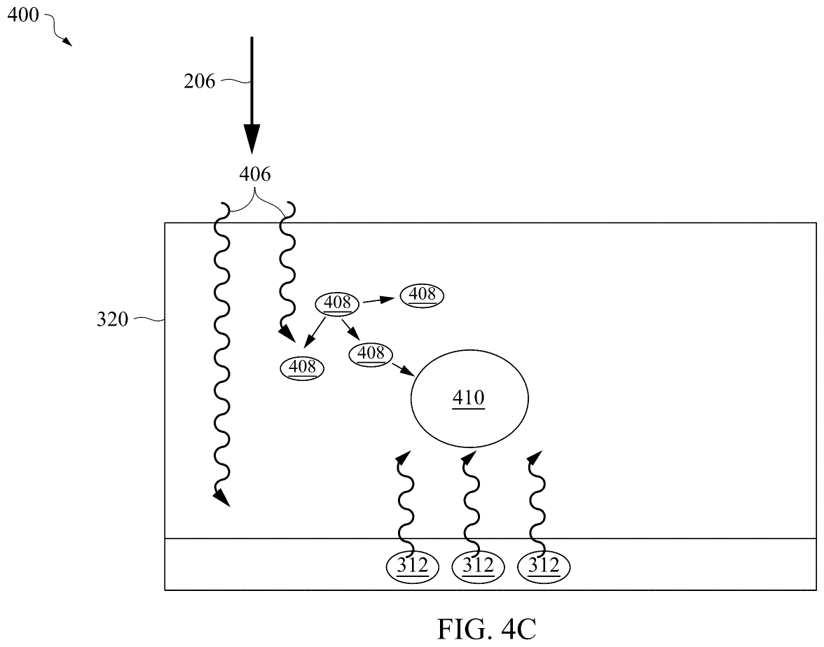

FIGS. 4A-4C are diagrams of an example implementation 400 of exposing a multiple-layer photoresist described herein to radiation 206 to form a pattern in the multiple-layer photoresist. In some implementations, one or more of the operations described in connection with FIGS. 4A-4C may be performed using an exposure tool 104 and/or another semiconductor processing tool. In some implementations, one or more of the operations described in connection with FIGS. 4A-4C may be performed after one or more of the operations described in connection with FIGS. 3A-3F.

As shown in FIG. 4A, the semiconductor substrate 210 may be positioned on wafer stage 236 of the exposure tool 104 for the exposure operation. The radiation 206 (e.g., EUV radiation) is directed onto the photoresist layer 320 on the semiconductor substrate 210 in the exposure operation.

As shown in FIG. 4B, the exposure of the photoresist layer 320 to the radiation 206 results in formation of a pattern 402 in the photoresist layer 320, which includes portions of the photoresist layer 320 that are exposed to the radiation 206. Unexposed portions 404 of the photoresist layer 320 remain on the semiconductor substrate 210 after the exposure operation.

As shown in FIG. 4C, in the exposed portions of the pattern 402 in the photoresist layer 320, photons 406 of the radiation 206 are absorbed in the photoresist layer 320. The photons 406 that are absorbed react with the material of the photoresist layer 320, resulting in formation of secondary electrons 408 (e.g., thermal electrons) in the photoresist layer 320. The secondary electrons 408 cause a reaction 410 with the acid generator component 312 that diffused into the photoresist layer 320.

As indicated above, FIGS. 4A-4C are provided as an example. Other examples may differ from what is described with regard to FIGS. 4A-4C.

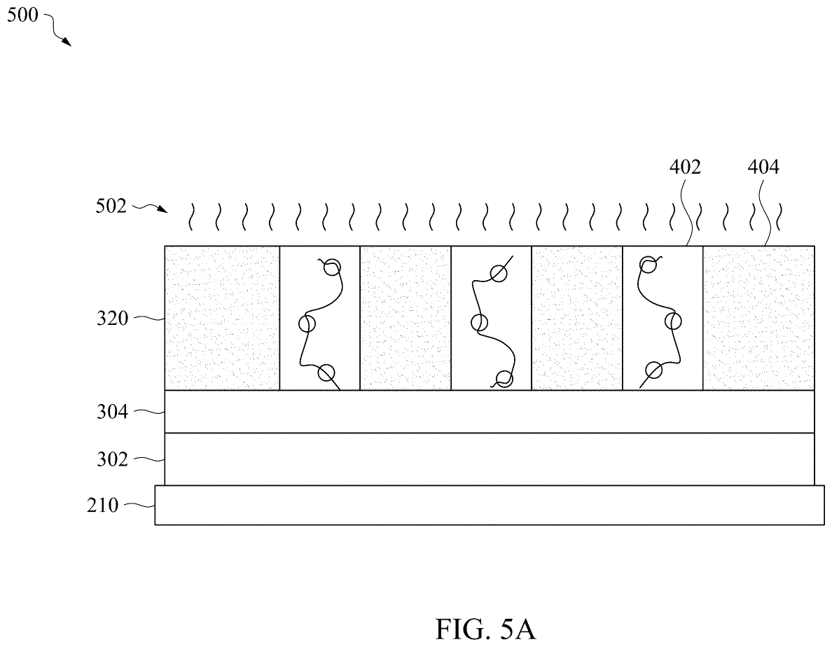

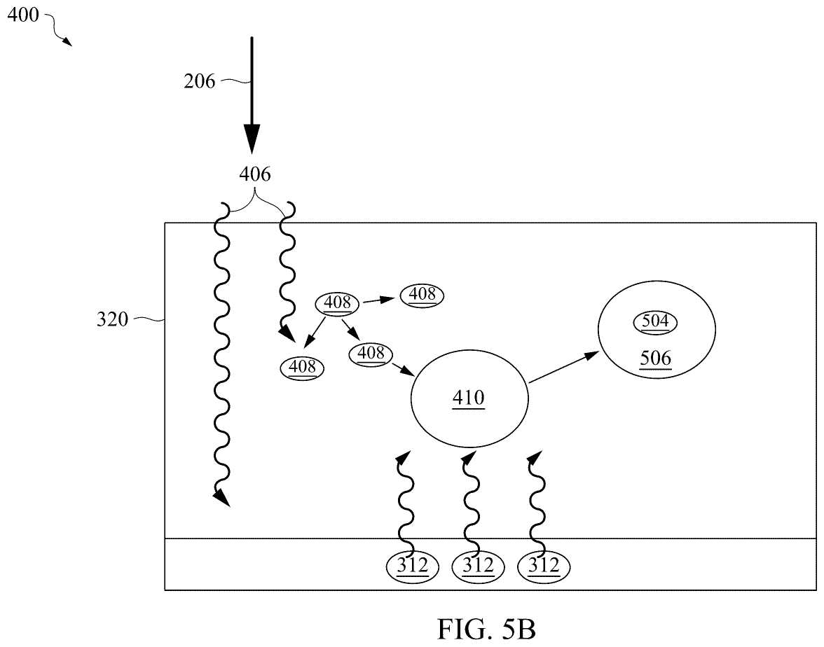

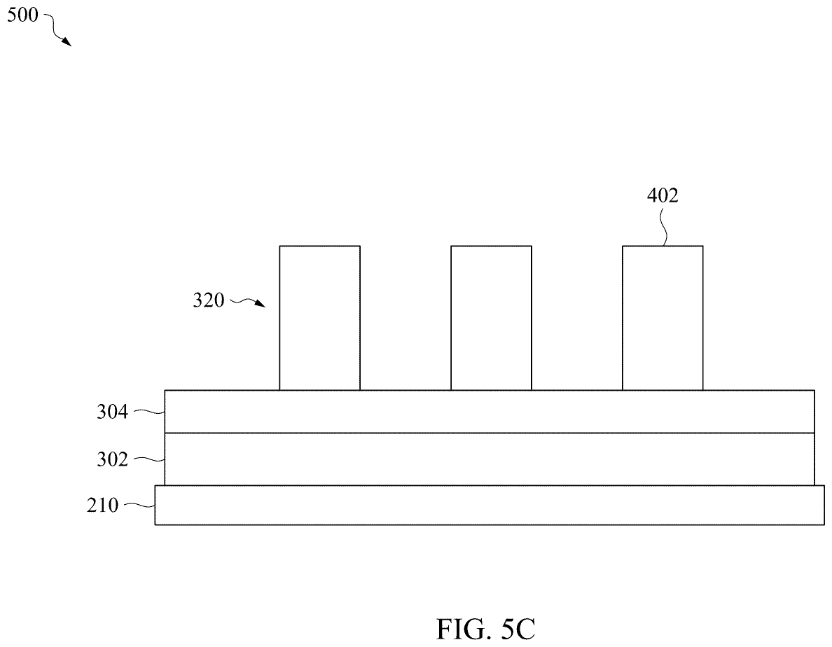

FIGS. 5A-5C are diagrams of an example implementation 500 of developing a pattern 402 formed in a photoresist layer 320 of a multiple-layer photoresist described herein. In some implementations, one or more of the operations described in connection with FIGS. 5A-5C may be performed using a developer tool 106 and/or another semiconductor processing tool. In some implementations, one or more of the operations described in connection with FIGS. 5A-5C may be performed after one or more of the operations described in connection with FIGS. 3A-3F and/or 4A-4C.

As shown in FIG. 5A, one or more post-exposure bake operations 502 may be performed on the photoresist layer 320 after exposure of the photoresist layer 320 to the radiation 206. The post-exposure bake operation(s) 502 may be performed to promote cross-linking of the photoresist material in the exposed portions of the photoresist layer 320, as shown in FIG. 5A. In some implementations, a plurality of post-exposure bake operations 502 may be performed such that a first post-exposure bake operation 502 is performed and a second post-exposure bake operation 502 is performed after the first post-exposure bake operation 502. The temperature of the second post-exposure bake operation(s) 502 may be greater relative to the temperature of the first post-exposure operation 502. In this way, performing a plurality of post-exposure bake operations 502 enables precise control over the temperature ramping of the post-exposure bake of the photoresist layer 320.

As shown in FIG. 5B, the post-exposure back operation(s) 502 initiate the formation of a photoacid in the photoresist layer 320. A photo acid 504 generated from the acid generator component 312, which causes acid diffusion 506 into the photoresist layer 320 reacts with the thermal electrons at 410 to generate the photo acid 504, which causes deprotection spheres to form in the photoresist layer 320.

The PDB component 322 in the photoresist layer 320 may neutralize the photo acid 504 such that the formation of the photo acid 504 is controlled in a manner which permits formation of the pattern 402 having a low LWR. As described above, the high uniformity of the polar groups (e.g., the monomers 316 and 318) across the top surface of the photoresist underlayer 304 promotes uniform distribution of the PDB component 322 in the photoresist layer 320 and suppresses aggregation of the PDB component 322 at the bottom of the photoresist layer 320. If the distribution of the polar groups across the top surface of the photoresist underlayer 304 were not uniform, areas of high concentration of the PDB component 322 might otherwise occur in the photoresist layer 320. These areas of high concentration of the PDB component 322 might quench the generation of photo acid 504 too quickly, resulting in underdeveloped portions of exposed photoresist layer 320, which would otherwise result in residual material (e.g., photoresist scum) remaining over the semiconductor substrate 210. Accordingly, the formation of the photoresist underlayer 304 such that the polymer material 306 has a high distribution uniformity of polar groups across the top surface of the photoresist underlayer 304 and promotes full development of the pattern 402 in the photoresist layer 320, which reduces the amount of residual material remaining over the semiconductor substrate 210, and reduces the likelihood of defect formation in structures formed in the layer 302 and/or in the semiconductor substrate 210 using the pattern 402.

In some implementations, a post-exposure bake operation 502 is performed for a time duration that is in a range of approximately 60 seconds to approximately 600 seconds to ensure sufficient cross-linking density in the exposed portions of the pattern 402 formed in the photoresist layer 320 without causing over cross-linking (which may lead to an increased amount of photoresist residue remaining on the semiconductor substrate 210 after a development operation). However, other values for the time duration for each post-exposure bake operation are within the scope of the present disclosure.

In some implementations, a post-exposure bake operation 502 may be performed at a temperature that is in a range of approximately 80 degrees Celsius to approximately 350 degrees Celsius to ensure sufficient generation of photo acid 504 in the photoresist layer 320 without causing over cross-linking in the photoresist layer 320. However, other values for the temperature of the post-exposure operation 502 are within the scope of the present disclosure.

As shown in FIG. 5C, the pattern 402 is developed in the photoresist layer 320 after the exposure operation and the one or more post-exposure bake operations 502. The developer tool 106 may be used to perform a development operation to develop the pattern 402. The time duration of the development operation may range from approximately 30 seconds to approximately 60 seconds. However, other values for the time duration are within the scope of the present disclosure.

The developer tool 106 may be used with various types of developers, such as 2-Heptanone and/or another type of developer. After the development operation is performed, the pattern 402 may be used in a subsequent semiconductor processing operation, which may include etching the layer 302 and/or the semiconductor substrate 210, implanting ions into the layer 302 and/or in the semiconductor substrate 210, patterning the layer 302 as a hard mask, and/or another type of semiconductor processing operation.

As indicated above, FIGS. 5A-5C are provided as an example. Other examples may differ from what is described with regard to FIGS. 5A-5C.

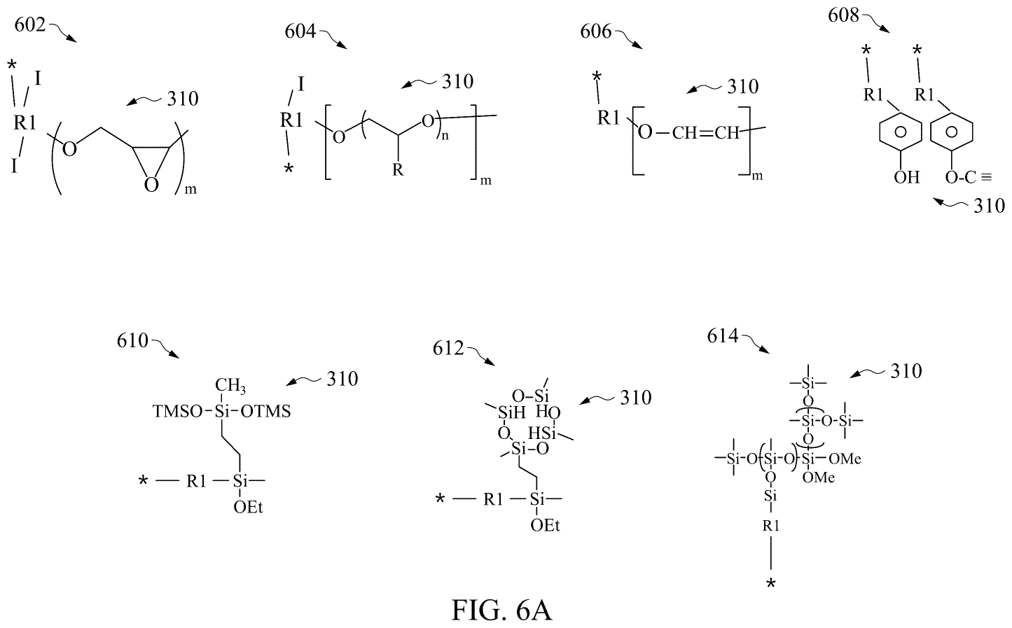

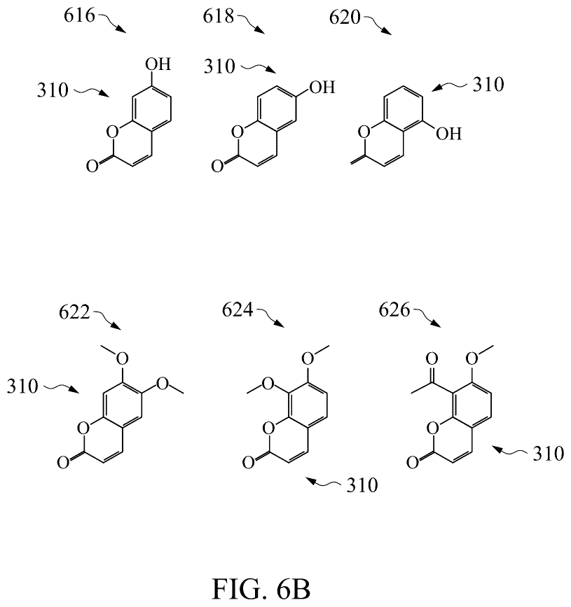

FIGS. 6A and 6B are diagrams of examples of materials that may be used for the R1 components and crosslinking group components 310 described herein. As shown in FIGS. 6A and 6B, the crosslinking group component 310 included in a polymer material 306 of a photoresist underlayer 304 may include one or more of the molecules 602-626 illustrated in FIGS. 6A and 6B. The molecules 602-626 of the crosslinking group component 310 may include a cross-linkable functional group, such as alkene, alkyne, triazene, a hydrocarbon group, halogen, —S—, —P—, —P(O₂)—, —C(═O)S—, —C(═O)O—, —O—, —N—, —C(═O)N—, —SO₂O—, —SO₂S—, —SO—, —SO₂—, a carboxyl group, ether, ketone, ester, epoxy, and/or aryl (e.g., phenyl), among other examples. In some implementations, a plurality of molecules of the crosslinking group component 310 may be bonded with a single R1 component, such as illustrated for molecules 602, 604, 606, and 608. In these implementations, m (e.g., the quantity of molecules 602, 604, 606, and/or 608 bonded to the same R1 component) may be included in a range of 1 to 12. However, other values for the range are within the scope of the present disclosure.

As indicated above, FIGS. 6A and 6B are provided as examples. Other examples may differ from what is described with regard to FIGS. 6A and 6B.

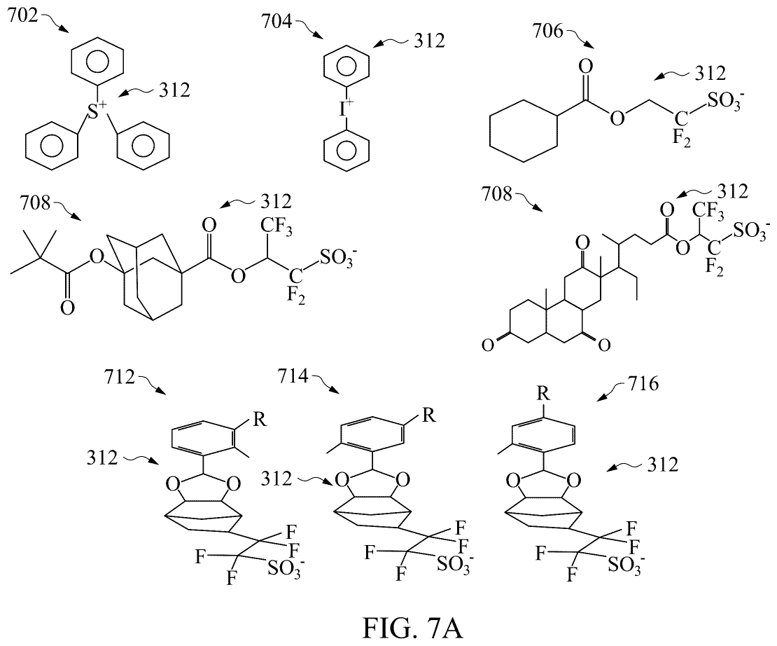

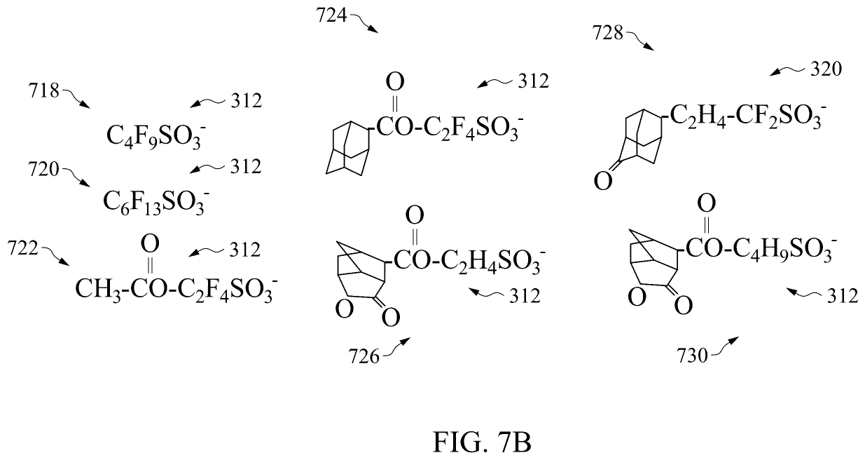

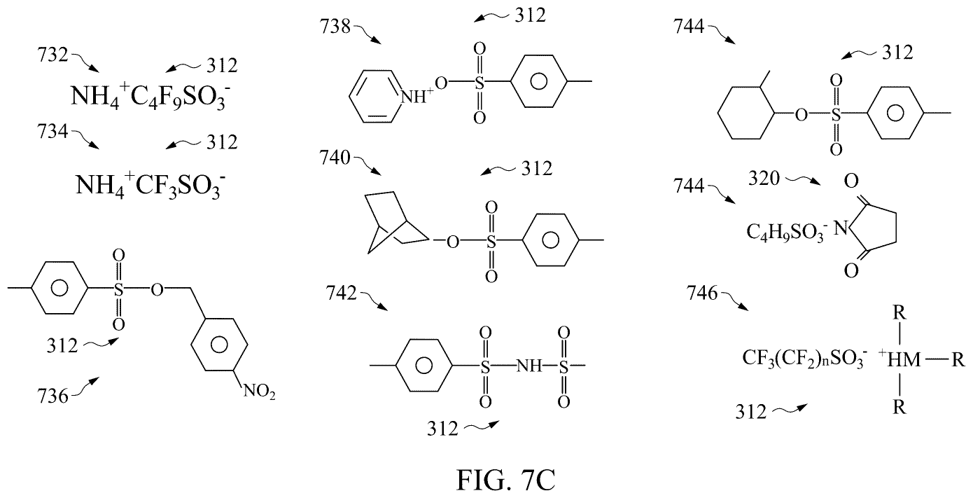

FIGS. 7A-7C are diagrams of examples of materials that may be used for the acid generator components 312 described herein. FIGS. 7A and 7B illustrate examples of PAG molecules 702-730, and FIG. 7C illustrates examples of TAG molecules 732-746.

A PAG acid generator component 312 may include one or more cations (corresponding to PAG molecules 702 and 704) and one or more anions (corresponding to PAG molecules 706-730). An R component of the PAG molecules 712-716 may be cyclic or noncyclic, saturated or unsaturated, substituted or unsubstituted, and/or branched or unbranched. The R component may include a hydrocarbon group having a quantity of carbon atoms in a range of 1 carbon atom to 9 carbon atoms (e.g., a C1-C9 hydrocarbon group), such as an alkyl group and/or alkenyl group, among other examples. However, other values for the range are within the scope of the present disclosure. If substituted, the C1-C9 hydrocarbon group may be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, epoxy, and/or aryl (e.g., phenyl), among other examples.

A TAG acid generator component 312 may include one or more of the TAG molecules 732-746. An R component of the TAG molecule 746 may be cyclic or noncyclic, saturated or unsaturated, substituted or unsubstituted, and/or branched or unbranched. The R component may include a hydrocarbon group having a quantity of carbon atoms in a range of 1 carbon atom to 9 carbon atoms (e.g., a C1-C9 hydrocarbon group), such as an alkyl group and/or alkenyl group, among other examples. However, other values for the range are within the scope of the present disclosure. If substituted, the C1-C9 hydrocarbon group may be substituted with halogen, —S—, —P—, —P(O₂)—, —C(═O)S—, —C(═O)O—, —O—, —N—, —C(═O)N—, —SO₂O—, —SO₂S—, —SO—, —SO₂—, carboxyl group, ether, ketone, ester, epoxy, and/or aryl (e.g., phenyl), among other examples. In some implementations, n in the TAG molecule 746 may be included in a range of 1 to 4. However, other values for the range are within the scope of the present disclosure.

As indicated above, FIGS. 7A-7C are provided as examples. Other examples may differ from what is described with regard to FIGS. 7A-7C.

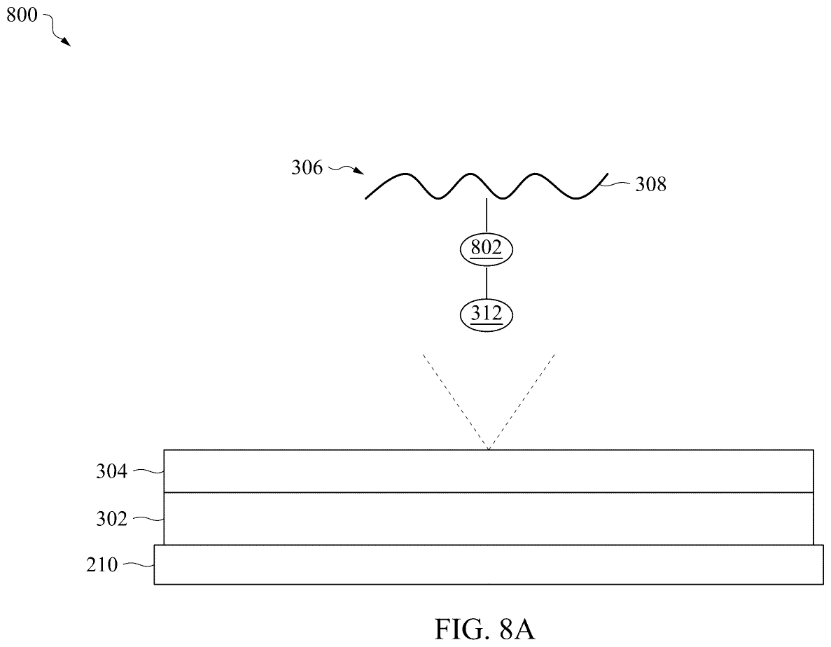

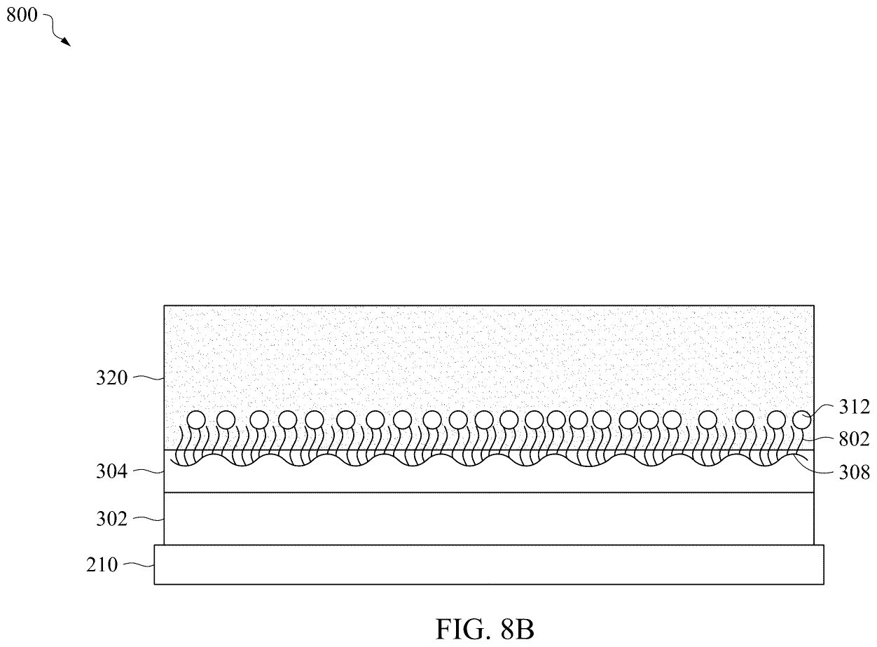

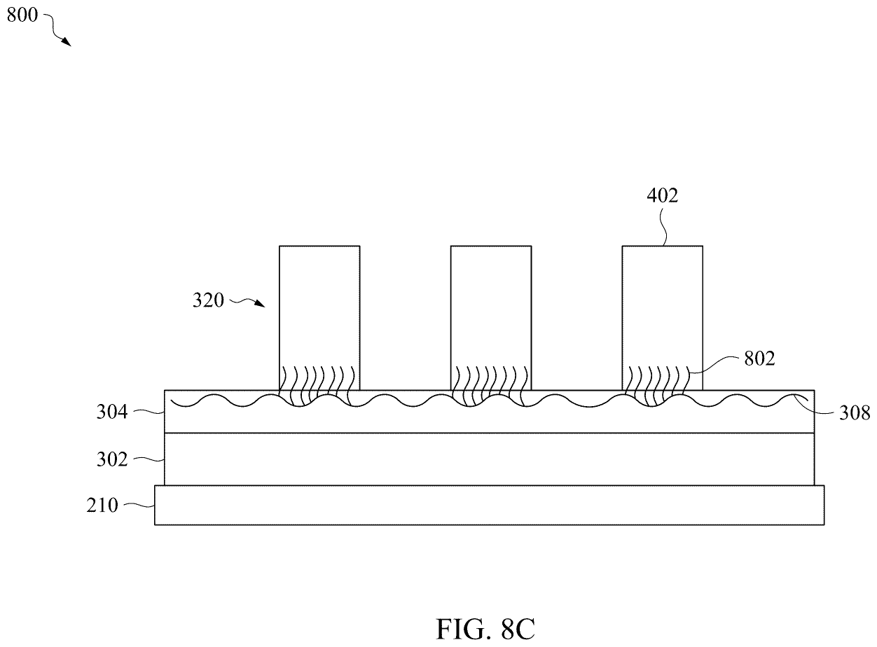

FIGS. 8A-8C are diagrams of an example implementation 800 of a multiple-layer photoresist described herein. As shown in FIGS. 8A-8C, the multiple-layer photoresist includes the photoresist underlayer 304 and the photoresist layer 320, similar to the multiple-layer photoresist in the example implementation 300 described in connection with FIGS. 3A-3F. As further shown in FIGS. 8A-8C, the multiple-layer photoresist is formed over a semiconductor substrate 210, and may be formed on a layer 302 that is on the semiconductor substrate 210.

As shown in FIG. 8A, the photoresist underlayer 304 includes a polymer material 306. The polymer material 306 includes a main polymer chain 308 and an acid generator component side chain 802 that links an acid generator component 312 to the main polymer chain 308. The acid generator component side chain 802 includes a branched or unbranched, cyclic or noncyclic, saturated or unsaturated hydrocarbon group. The hydrocarbon group may include 5 carbon atoms to 40 carbon atoms (e.g., a C5-C40 hydrocarbon group) that are bonded by one or more types of bonds (e.g., —C═C— and/or —C≡C—). However, other values for the range are within the scope of the present disclosure. If substituted, the acid generator component side chain 802 may include a halogen, —S—, —P—, —P(O₂)—, —C(═O)S—, —C(═O)O—, —O—, —N—, —C(═O)N—, —SO₂O—, —SO₂S—, —SO—, —SO₂—, a carboxylic acid, an ether, a ketone, an ester, an epoxy, and/or benzene unit, among other examples.

As shown in FIGS. 8B and 8C, acid generator component side chains 802 couple the acid generator component 312 with the main polymer chain 308 of the polymer material 306 to control the diffusion of the acid generator component 312 into the photoresist layer 320. This prevents (or suppresses) uncontrollable diffusion of the acid generator component 312 into the photoresist layer 320, and promotes a uniform concentration of the acid generator component 312 at the bottom of the photoresist layer 320. When the exposure operation described in FIGS. 4A-4C is performed, and the pattern 402 in the photoresist layer 320 is developed (as described in connection with FIGS. 5A-5C), the acid generator component 312 retained at the bottom of the photoresist layer 320 promotes formation of the photo acid 504 at the bottom of the photoresist layer 320. The photo acid 504 generated at the bottom of the photoresist layer 320 enables the bottommost portions of the photoresist layer 320 to be developed and removed when developing the pattern 402. This reduces the likelihood that residual photoresist material is retained in the photoresist layer 320, which may reduce LWR and/or may decrease LCDU in features that are formed in the layer 302 and/or in the semiconductor substrate 210 using the multiple-layer photoresist. The reduced LWR and/or the decreased LCDU may enable the features to be formed to smaller dimensions and/or increased uniformity, thereby increasing yield of semiconductor structures formed on the semiconductor substrate 210.

As indicated above, FIGS. 8A-8C are provided as an example. Other examples may differ from what is described with regard to FIGS. 8A-8C.

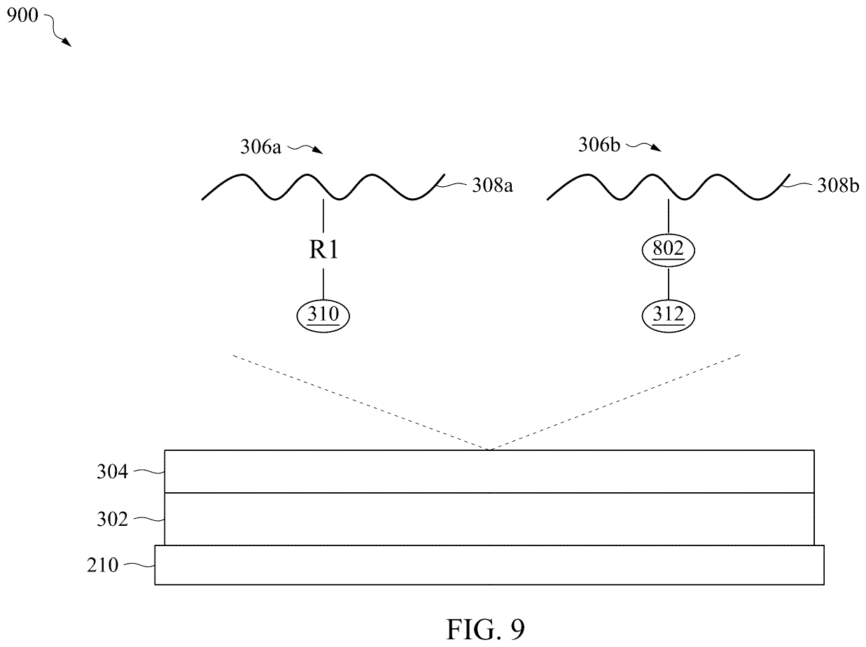

FIG. 9 is a diagram of an example implementation 900 of a photoresist underlayer 304 described herein. As shown in FIG. 9, in the example implementation 900, the photoresist underlayer 304 includes a plurality of polymer materials, including a polymer material 306a and a polymer material 306b.

The polymer material 306a and the polymer material 306b may include different compositions described herein. For example, the polymer material 306a may include a main polymer chain 308a and a crosslinking group component 310 joined to the main polymer chain 308a by an R1 component. The polymer material 306a may be included in the photoresist underlayer 304 to promote a uniform distribution of polar groups in the photoresist underlayer 304.

The polymer material 306b may include a main polymer chain 308b, a plurality of acid generator component side chains 802, and an acid generator component 312 joined to the main polymer chain 308b by the plurality of acid generator component side chains 802. The polymer material 306b may be included in the photoresist underlayer 304 to control the diffusion of the acid generator component 312 into a photoresist layer 320 on the photoresist underlayer 304.

As indicated above, FIG. 9 is provided as an example. Other examples may differ from what is described with regard to FIG. 9.

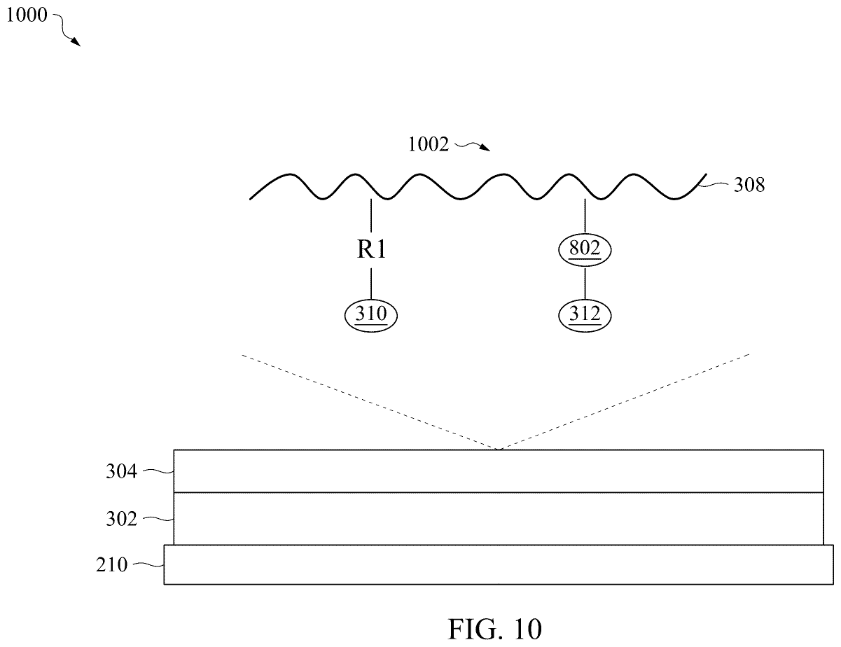

FIG. 10 is a diagram of an example implementation 1000 of a photoresist underlayer 304 described herein. As shown in FIG. 10, in the example implementation 1000, the photoresist underlayer 304 includes a co-polymer material 1002.

The co-polymer material 1002 includes a main polymer chain 308. The co-polymer material 1002 may include a crosslinking group component 310 joined to the main polymer chain 308 by an R1 component to promote a uniform distribution of polar groups in the photoresist underlayer 304. The co-polymer material 1002 may also include a plurality of acid generator component side chains 802, and an acid generator component 312 joined to the main polymer chain 308 by the plurality of acid generator component side chains 802 to control the diffusion of the acid generator component 312 into a photoresist layer 320 on the photoresist underlayer 304.

As indicated above, FIG. 10 is provided as an example. Other examples may differ from what is described with regard to FIG. 10.

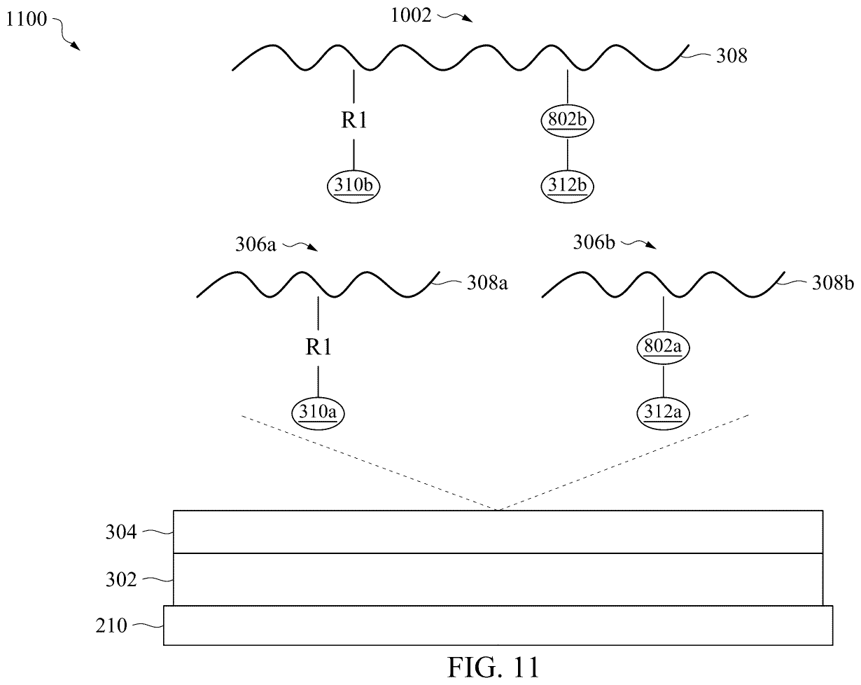

FIG. 11 is a diagram of an example implementation 1100 of a photoresist underlayer 304 described herein. As shown in FIG. 11, in the example implementation 1100, the photoresist underlayer 304 includes a plurality of polymer materials, including a polymer material 306a, a polymer material 306b, and a co-polymer material 1002.

The polymer material 306a may include a main polymer chain 308a and a crosslinking group component 310a joined to the main polymer chain 308a by an R1 component. The polymer material 306a may be included in the photoresist underlayer 304 to promote a uniform distribution of polar groups in the photoresist underlayer 304.

The polymer material 306b may include a main polymer chain 308b, a plurality of acid generator component side chains 802a, and an acid generator component 312a joined to the main polymer chain 308b by the plurality of acid generator component side chains 802. The polymer material 306b may be included in the photoresist underlayer 304 to control the diffusion of the acid generator component 312a into a photoresist layer 320 on the photoresist underlayer 304.

The co-polymer material 1002 includes a main polymer chain 308c. The co-polymer material 1002 may include a crosslinking group component 310b joined to the main polymer chain 308c by an R1 component to promote a uniform distribution of polar groups in the photoresist underlayer 304. The co-polymer material 1002 may also include a plurality of acid generator component side chains 802b, and an acid generator component 312b joined to the main polymer chain 308c by the plurality of acid generator component side chains 802b to control the diffusion of the acid generator component 312c into a photoresist layer 320 on the photoresist underlayer 304.

As indicated above, FIG. 11 is provided as an example. Other examples may differ from what is described with regard to FIG. 11.

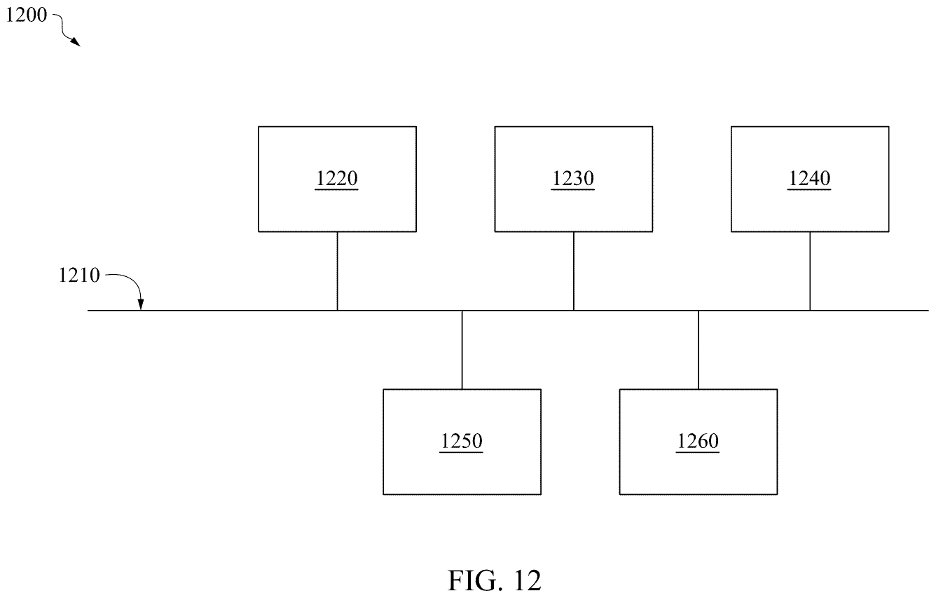

FIG. 12 is a diagram of example components of a device 1200 described herein. In some implementations, one or more of the semiconductor processing tools 102-108 and/or the wafer/die transport tool 110 may include one or more devices 1200 and/or one or more components of the device 1200. As shown in FIG. 12, the device 1200 may include a bus 1210, a processor 1220, a memory 1230, an input component 1240, an output component 1250, and/or a communication component 1260.

The bus 1210 may include one or more components that enable wired and/or wireless communication among the components of the device 1200. The bus 1210 may couple together two or more components of FIG. 12, such as via operative coupling, communicative coupling, electronic coupling, and/or electric coupling. For example, the bus 1210 may include an electrical connection (e.g., a wire, a trace, and/or a lead) and/or a wireless bus. The processor 1220 may include a central processing unit, a graphics processing unit, a microprocessor, a controller, a microcontroller, a digital signal processor, a field-programmable gate array, an application-specific integrated circuit, and/or another type of processing component. The processor 1220 may be implemented in hardware, firmware, or a combination of hardware and software. In some implementations, the processor 1220 may include one or more processors capable of being programmed to perform one or more operations or processes described elsewhere herein.

The memory 1230 may include volatile and/or nonvolatile memory. For example, the memory 1230 may include random access memory (RAM), read only memory (ROM), a hard disk drive, and/or another type of memory (e.g., a flash memory, a magnetic memory, and/or an optical memory). The memory 1230 may include internal memory (e.g., RAM, ROM, or a hard disk drive) and/or removable memory (e.g., removable via a universal serial bus connection). The memory 1230 may be a non-transitory computer-readable medium. The memory 1230 may store information, one or more instructions, and/or software (e.g., one or more software applications) related to the operation of the device 1200. In some implementations, the memory 1230 may include one or more memories that are coupled (e.g., communicatively coupled) to one or more processors (e.g., processor 1220), such as via the bus 1210. Communicative coupling between a processor 1220 and a memory 1230 may enable the processor 1220 to read and/or process information stored in the memory 1230 and/or to store information in the memory 1230.

The input component 1240 may enable the device 1200 to receive input, such as user input and/or sensed input. For example, the input component 1240 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1250 may enable the device 1200 to provide output, such as via a display, a speaker, and/or a light-emitting diode. The communication component 1260 may enable the device 1200 to communicate with other devices via a wired connection and/or a wireless connection. For example, the communication component 1260 may include a receiver, a transmitter, a transceiver, a modem, a network interface card, and/or an antenna.

The device 1200 may perform one or more operations or processes described herein. For example, a non-transitory computer-readable medium (e.g., memory 1230) may store a set of instructions (e.g., one or more instructions or code) for execution by the processor 1220. The processor 1220 may execute the set of instructions to perform one or more operations or processes described herein. In some implementations, execution of the set of instructions, by one or more processors 1220, causes the one or more processors 1220 and/or the device 1200 to perform one or more operations or processes described herein. In some implementations, hardwired circuitry may be used instead of or in combination with the instructions to perform one or more operations or processes described herein. Additionally, or alternatively, the processor 1220 may be configured to perform one or more operations or processes described herein. Thus, implementations described herein are not limited to any specific combination of hardware circuitry and software.

The number and arrangement of components shown in FIG. 12 are provided as an example. The device 1200 may include additional components, fewer components, different components, or differently arranged components than those shown in FIG. 12. Additionally, or alternatively, a set of components (e.g., one or more components) of the device 1200 may perform one or more functions described as being performed by another set of components of the device 1200.

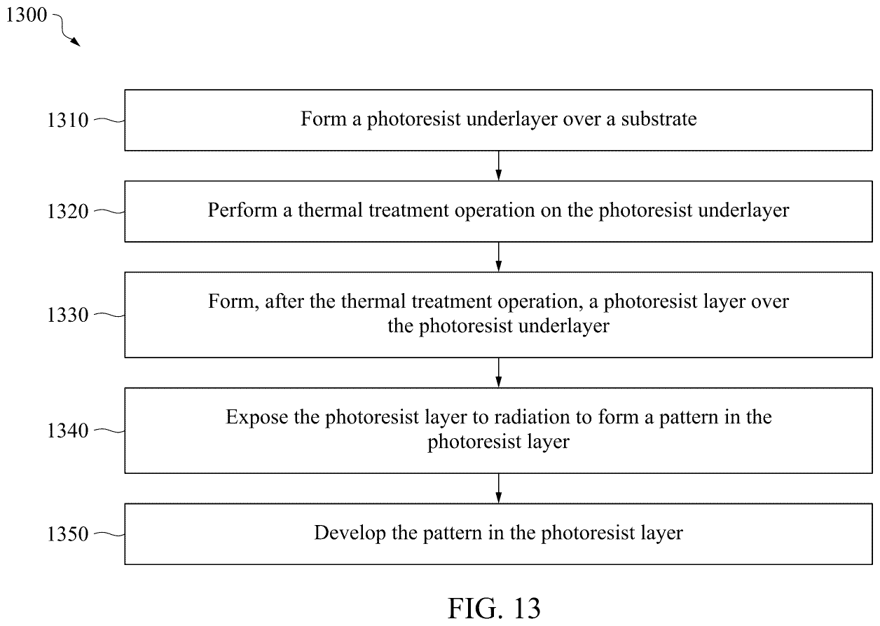

FIG. 13 is a flowchart of an example process 1300 associated with forming a multiple-layer photoresist on a semiconductor substrate described herein. In some implementations, one or more process blocks of FIG. 13 are performed using one or more semiconductor processing tools (e.g., one or more of the semiconductor processing tools 102-108). Additionally, or alternatively, one or more process blocks of FIG. 13 may be performed using one or more components of device 1200, such as processor 1220, memory 1230, input component 1240, output component 1250, and/or communication component 1260.

As shown in FIG. 13, process 1300 may include forming a photoresist underlayer over a substrate (block 1310). For example, one or more of the semiconductor processing tools 102-108 may be used to form a photoresist underlayer 304 over a semiconductor substrate 210, as described herein. In some implementations, the photoresist underlayer 304 includes a polymer material 306 and an acid generator component 312.

As further shown in FIG. 13, process 1300 may include performing a treatment operation on the photoresist underlayer (block 1320). For example, one or more of the semiconductor processing tools 102-108 may be used to perform a treatment operation 314 on the photoresist underlayer 304, as described herein. In some implementations, a polar group distribution uniformity across a top surface of the photoresist underlayer after the treatment operation is greater than the polar group distribution uniformity across the top surface of the photoresist underlayer prior to the treatment operation. In some implementations, a polar group distribution uniformity across a top surface of the photoresist underlayer after the thermal treatment operation satisfies a uniformity threshold. In some implementations, the treatment operation includes at least one of a thermal treatment operation, a UV treatment operation, an e-beam treatment operation, and/or another type of treatment operation.

As further shown in FIG. 13, process 1300 may include forming, after the treatment operation, a photoresist layer over the photoresist underlayer (block 1330). For example, one or more of the semiconductor processing tools 102-108 may be used to form, after the treatment operation 314, a photoresist layer 320 over the photoresist underlayer 304, as described herein.

As further shown in FIG. 13, process 1300 may include exposing the photoresist layer to radiation to form a pattern in the photoresist layer (block 1340). For example, one or more of the semiconductor processing tools 102-108 may be used to expose the photoresist layer to radiation 206 to form a pattern 402 in the photoresist layer 320, as described herein. In some implementations, the acid generator component 312 in the photoresist underlayer 304 generates an acid (e.g., a photo acid 504), based on at least one of the treatment operation or the radiation 206, that results in formation of the pattern 402 in the photoresist layer 320.

As further shown in FIG. 13, process 1300 may include developing the pattern in the photoresist layer (block 1350). For example, one or more of the semiconductor processing tools 102-108 may be used to develop the pattern 402 in the photoresist layer 320, as described herein.

Process 1300 may include additional implementations, such as any single implementation or any combination of implementations described below and/or in connection with one or more other processes described elsewhere herein.

In a first implementation, the photoresist layer 320 includes a PDB component 322, and the polar group distribution uniformity satisfying the uniformity threshold promotes uniform distribution of the PDB component 322 in the photoresist layer 320.

In a second implementation, alone or in combination with the first implementation, the photoresist layer 320 includes a PDB component 322, and the polar group distribution uniformity satisfying the uniformity threshold suppresses aggregation of the PDB component 322 at a bottom of the photoresist layer 320.

In a third implementation, alone or in combination with one or more of the first and second implementations, the photoresist underlayer 304 includes at least one of a middle layer, a bottom layer, or a BARC layer.

In a fourth implementation, alone or in combination with one or more of the first through third implementations, performing the treatment operation 314 includes performing the treatment operation 314 at a temperature that is included in a range of greater than approximately 100 degrees Celsius to approximately 400 degrees Celsius.

In a fifth implementation, alone or in combination with one or more of the first through fourth implementations, the uniformity threshold is included in a range of approximately 35% to approximately 100%.

In a sixth implementation, alone or in combination with one or more of the first through fifth implementations, forming the photoresist underlayer 304 includes forming the photoresist underlayer 304 to a thickness (dimension D1) that is included in a range of approximately 5 angstroms to approximately 500 angstroms.

In a seventh implementation, alone or in combination with one or more of the first through fifth implementations, the photoresist underlayer 304 includes a main polymer chain (e.g., a polymer chain 308, a polymer chain 308a, a polymer chain 308b), a plurality of acid generator component side chains 802 coupled with the main polymer chain, and the acid generator component 312 coupled with the plurality of acid generator component side chains 802.

In an eighth implementation, alone or in combination with one or more of the first through seventh implementations, the main polymer chain is a first main polymer chain in a first polymer material 306a included in the photoresist underlayer 304, and where a second polymer material 306b, included in the photoresist underlayer 304, includes a second main polymer chain 308b, a crosslinking group component 310, and a plurality of polar groups (e.g., a monomer 316, a monomer 318).

In a ninth implementation, alone or in combination with one or more of the first through eighth implementations, the photoresist underlayer 304 includes a co-polymer material 1002 that includes the main polymer chain, the plurality of acid generator component side chains 802, the acid generator component 312, a crosslinking group component 310, and a plurality of polar groups (e.g., a monomer 316, a monomer 318).

In a tenth implementation, alone or in combination with one or more of the first through ninth implementations, the main polymer chain is a first main polymer chain 308c included in the photoresist underlayer 304, the plurality of acid generator component side chains 802 is a first plurality of acid generator component side chains 802b included in the photoresist underlayer 304, the acid generator component 312 is a first acid generator component 312b included in the photoresist underlayer 304, and a polymer material 306b, included in the photoresist underlayer 304, includes a second main polymer chain 308b, a second plurality of acid generator component side chains 802a coupled with the second main polymer chain 308b, and a second acid generator component 312a coupled with the second plurality of acid generator component side chains 802a.

In an eleventh implementation, alone or in combination with one or more of the first through tenth implementations, the main polymer chain is a first main polymer chain 308c included in the photoresist underlayer 304, the crosslinking group component 310 is a first crosslinking group component 310b included in the photoresist underlayer 304, the plurality of polar groups is a first plurality of polar groups included in the photoresist underlayer, and a polymer material 306a, included in the photoresist underlayer 304, includes a second main polymer chain 308a, a second crosslinking group component 310a, and a second plurality of polar groups (e.g., a monomer 316, a monomer 318).

In a twelfth implementation, alone or in combination with one or more of the first through eleventh implementations, the main polymer chain is a first main polymer chain 308c included in the photoresist underlayer 304, the plurality of acid generator component side chains 802 is a first plurality of acid generator component side chains 802b included in the photoresist underlayer 304, the acid generator component 312 is a first acid generator component 312b included in the photoresist underlayer 304, the crosslinking group component 310 is a first crosslinking group component 310b included in the photoresist underlayer 304, the plurality of polar groups is a first plurality of polar groups included in the photoresist underlayer 304, a first polymer material 306a, included in the photoresist underlayer 304, includes a second main polymer chain 308a, a second crosslinking group component 310a, and a second plurality of polar groups (e.g., a monomer 316, a monomer 318), and a second polymer material 306b, included in the photoresist underlayer 304, includes a third main polymer chain 308b, a second plurality of acid generator component side chains 802a coupled with the third main polymer chain 308b, and a second acid generator component 312a coupled with the second plurality of acid generator component side chains 802a.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

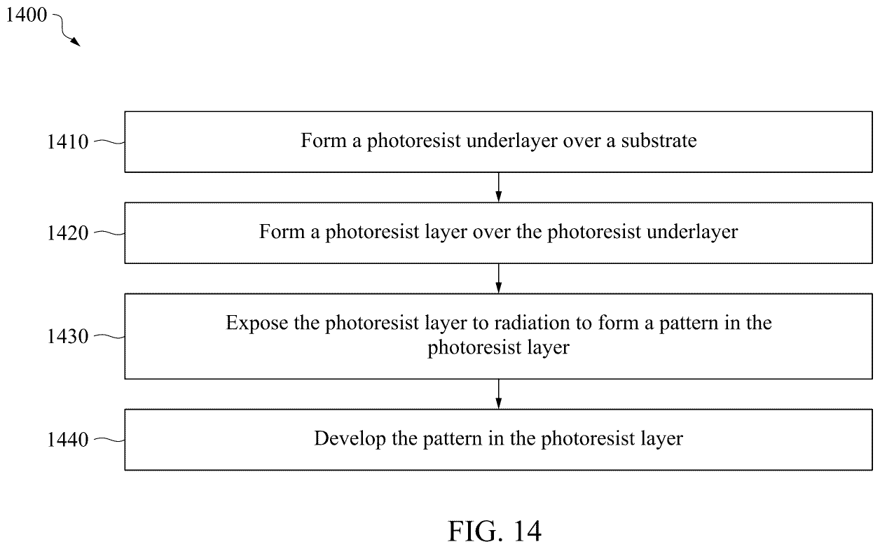

FIG. 14 is a flowchart of an example process 1400 associated with forming a multiple-layer photoresist on a semiconductor substrate described herein. In some implementations, one or more process blocks of FIG. 14 are performed using one or more semiconductor processing tools (e.g., one or more of the semiconductor processing tools 102-108). Additionally, or alternatively, one or more process blocks of FIG. 14 may be performed using one or more components of device 1200, such as processor 1220, memory 1230, input component 1240, output component 1250, and/or communication component 1260.

As shown in FIG. 14, process 1400 may include forming a photoresist underlayer over a substrate (block 1410). For example, one or more of the semiconductor processing tools 102-108 may be used to form a photoresist underlayer 304 over a semiconductor substrate 210, as described herein. In some implementations, the photoresist underlayer 304 includes a main polymer chain 308, a plurality of acid generator component side chains 802 coupled with the main polymer chain 308, and an acid generator component 312 coupled with the plurality of acid generator component side chains 802.

As further shown in FIG. 14, process 1400 may include forming a photoresist layer over the photoresist underlayer (block 1420). For example, one or more of the semiconductor processing tools 102-108 may be used to form a photoresist layer 320 over the photoresist underlayer 304, as described herein.

As further shown in FIG. 14, process 1400 may include exposing the photoresist layer to radiation to form a pattern in the photoresist layer (block 1430). For example, one or more of the semiconductor processing tools 102-108 may be used to expose the photoresist layer 320 to radiation 206 to form a pattern 402 in the photoresist layer, as described herein. In some implementations, the acid generator component 312 in the photoresist underlayer reacts with the radiation to form an acid (e.g., a photo acid 504) that results in formation of the pattern 402 in the photoresist layer 320.

As further shown in FIG. 14, process 1400 may include developing the pattern in the photoresist layer (block 1440). For example, one or more of the semiconductor processing tools 102-108 may be used to develop the pattern 402 in the photoresist layer 320, as described herein.

Process 1400 may include additional implementations, such as any single implementation or any combination of implementations described below and/or in connection with one or more other processes described elsewhere herein.

In a first implementation, the plurality of acid generator component side chains 802 includes a plurality of hydrocarbon group bonding structures, halogen, —S—, —P—, —P(O₂)—, —C(═O)S—, —C(═O hydrocarbon group) O—, —O—, —N—, —C(═O)N—, —SO₂O—, —SO₂S—, —SO—, or —SO₂—.

In a second implementation, alone or in combination with the first implementation, a hydrocarbon group bonding structure, of the plurality of hydrocarbon group bonding structures, is included in a range of a 5 carbon atoms hydrocarbon group to a 40 carbon atoms hydrocarbon group.

In a third implementation, alone or in combination with one or more of the first and second implementations, the plurality of acid generator component side chains 802 includes at least one of a carboxylic acid, an ether, a ketone, an ester, an epoxy, or a benzene unit.

In a fourth implementation, alone or in combination with one or more of the first through third implementations, the plurality of acid generator component side chains 802 includes a cation and an anion.

In a fifth implementation, alone or in combination with one or more of the first through fourth implementations, a length of an acid generator component side chain 802, of the plurality of acid generator component side chains 802, is included in a range of approximately 1 nanometer to approximately 10 nanometers.

In a sixth implementation, alone or in combination with one or more of the first through fifth implementations, the acid generator component 312 diffuses into the photoresist layer 320, and the plurality of acid generator component side chains 802 retain the acid generator component 312 at a bottom of the photoresist layer 320.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a semiconductor device may be manufactured using a multiple-layer photoresist. The multiple-layer photoresist is formed of one or more materials that reduce the likelihood of and/or the amount of residual material retained in a photoresist layer of the multiple-layer photoresist after the photoresist layer is exposed to EUV radiation and developed. In some implementations, a photoresist underlayer of the multiple-layer photoresist includes a polymer having a highly uniform distribution of polar group monomers. Additionally and/or alternatively, the photoresist underlayer includes a polymer that includes a main chain and a plurality of side chains coupled with the main chain. The side chains include an acid generator component such as a PAG and/or a TAG, among other examples. Since the acid generator component is coupled with the main chain of the polymer by the side chains as opposed to uncontrollably diffusing into the photoresist layer, the acid generated by the acid generator component upon exposure to EUV radiation collects under the bottom of the photoresist layer in a uniform manner and enables the bottommost portions of the photoresist layer to be developed and removed. This reduces the likelihood that residual photoresist material is retained in the photoresist layer, which may reduce LWR and/or may decrease LCDU in features that are formed in the semiconductor device using the multiple-layer photoresist. The reduced LWR and/or the decreased LCDU may enable the features to be formed to smaller dimensions and/or increased uniformity, thereby increasing yield of semiconductor structures formed on the semiconductor device.

As described in greater detail above, some implementations described herein provide a method. The method includes forming a photoresist underlayer over a substrate, where the photoresist underlayer comprises a polymer and an acid generator component. The method includes performing a treatment operation on the photoresist underlayer, where a polar group distribution uniformity across a top surface of the photoresist underlayer after the treatment operation is greater than the polar group distribution uniformity across the top surface of the photoresist underlayer prior to the treatment operation. The method includes forming, after the treatment operation, a photoresist layer over the photoresist underlayer. The method includes exposing the photoresist layer to radiation to form a pattern in the photoresist layer, where the acid generator component in the photoresist underlayer reacts with the radiation to form an acid that results in formation of the pattern in the photoresist layer. The method includes developing the pattern in the photoresist layer.

As described in greater detail above, some implementations described herein provide a method. The method includes forming a photoresist underlayer over a substrate, where the photoresist underlayer comprises: a main polymer chain, a plurality of acid generator component side chains coupled with the main polymer chain, and an acid generator component coupled with the plurality of acid generator component side chains. The method includes forming a photoresist layer over the photoresist underlayer. The method includes exposing the photoresist layer to radiation to form a pattern in the photoresist layer, where the acid generator component in the photoresist underlayer reacts with the radiation to form an acid that results in formation of the pattern in the photoresist layer. The method includes developing the pattern in the photoresist layer.

As described in greater detail above, some implementations described herein provide a method. The method includes forming a photoresist underlayer over a substrate, where the photoresist underlayer comprises: a main polymer chain, a plurality of acid generator component side chains coupled with the main polymer chain, and an acid generator component coupled with the plurality of acid generator component side chains. The method includes performing a treatment operation on the photoresist underlayer, where a polar group distribution uniformity across a top surface of the photoresist underlayer after the treatment operation is greater than the polar group distribution uniformity across the top surface of the photoresist underlayer prior to the treatment operation. The method includes forming, after the treatment operation, a photoresist layer over the photoresist underlayer. The method includes exposing the photoresist layer to radiation to form a pattern in the photoresist layer, where the acid generator component in the photoresist underlayer reacts with the radiation to form an acid that results in formation of the pattern in the photoresist layer. The method includes developing the pattern in the photoresist layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a photoresist underlayer over a substrate,
wherein the photoresist underlayer comprises a polymer and an acid generator component;
performing a treatment operation on the photoresist underlayer,
wherein a polar group distribution uniformity across a top surface of the photoresist underlayer after the treatment operation is greater than the polar group distribution uniformity across the top surface of the photoresist underlayer prior to the treatment operation;
forming, after the treatment operation, a photoresist layer over the photoresist underlayer;
exposing the photoresist layer to radiation to form a pattern in the photoresist layer,
wherein the acid generator component in the photoresist underlayer generates an acid, based on at least one of the treatment operation or the radiation, that results in formation of the pattern in the photoresist layer; and
developing the pattern in the photoresist layer.

2. The method of claim 1, wherein the polar group distribution uniformity across the top surface of the photoresist underlayer after to the treatment operation satisfies a uniformity threshold; and
wherein the uniformity threshold is included in a range of approximately 35% to approximately 100%.

3. The method of claim 2, wherein the photoresist layer comprises a photo-decomposable base (PDB) component; and
wherein the polar group distribution uniformity satisfying the uniformity threshold promotes uniform distribution of the PDB component in the photoresist layer.

4. The method of claim 2, wherein the photoresist layer comprises a photo decomposable base (PDB) component; and
wherein the polar group distribution uniformity satisfying the uniformity threshold suppresses aggregation of the PDB component at a bottom of the photoresist layer.

5. The method of claim 1, wherein the photoresist underlayer comprises at least one of:
a middle layer (ML),
a bottom layer (BL), or
a bottom antireflective coating (BARC) layer.

6. The method of claim 1, wherein performing the treatment operation comprises:
performing a thermal treatment operation at a temperature that is included in a range of greater than approximately 100 degrees Celsius to approximately 400 degrees Celsius.

7. The method of claim 1, wherein the treatment operation comprises at least one of:
a thermal treatment operation,
an ultraviolet (UV) treatment operation, or
an electron-beam (e-beam) treatment operation.

8. A method, comprising:
forming a photoresist underlayer over a substrate,
wherein the photoresist underlayer comprises:
a main polymer chain,
a plurality of acid generator component side chains coupled with the main polymer chain, and
an acid generator component coupled with the plurality of acid generator component side chains;
forming a photoresist layer over the photoresist underlayer;
exposing the photoresist layer to radiation to form a pattern in the photoresist layer,
wherein the acid generator component in the photoresist underlayer reacts with the radiation to form an acid that results in formation of the pattern in the photoresist layer; and
developing the pattern in the photoresist layer.

9. The method of claim 8, wherein the plurality of acid generator component side chains comprises at least one of a plurality of hydrocarbon group bonding structures, halogen, —S—, —P—, —P(O₂)—, —C(═O)S—, —C(═O hydrocarbon group) O—, —O—, —N—, —C(═O)N—, —SO₂O—, —SO₂S—, —SO—, or —SO₂—.

10. The method of claim 9, wherein a hydrocarbon group bonding structure, of the plurality of hydrocarbon group bonding structures, is included in a range of a 5 carbon atoms hydrocarbon group to a 40 carbon atoms hydrocarbon group.

11. The method of claim 8, wherein the plurality of acid generator component side chains comprises at least one of:
a carboxylic acid,
an ether,
a ketone,
an ester,
an epoxy, or
a benzene unit.

12. The method of claim 8, wherein the plurality of acid generator component side chains comprises a cation and an anion.

13. The method of claim 8, wherein a length of an acid generator component side chain, of the plurality of acid generator component side chains, is included in a range of approximately 1 nanometer to approximately 10 nanometers.

14. The method of claim 8, wherein the acid generator component diffuses into the photoresist layer; and
wherein the plurality of acid generator component side chains retain the acid generator component at a bottom of the photoresist layer.

15. A method, comprising:
forming a photoresist underlayer over a substrate,
wherein the photoresist underlayer comprises:
a main polymer chain,
a plurality of acid generator component side chains coupled with the main polymer chain, and
an acid generator component coupled with the plurality of acid generator component side chains;
performing a treatment operation on the photoresist underlayer,
wherein a polar group distribution uniformity across a top surface of the photoresist underlayer after the treatment operation is greater than the polar group distribution uniformity across the top surface of the photoresist underlayer prior to the treatment operation;
forming, after the treatment operation, a photoresist layer over the photoresist underlayer;
exposing the photoresist layer to radiation to form a pattern in the photoresist layer,
wherein the acid generator component in the photoresist underlayer reacts with the radiation to form an acid that results in formation of the pattern in the photoresist layer; and
developing the pattern in the photoresist layer.

16. The method of claim 15, wherein the main polymer chain is a first main polymer chain in a first polymer material included in the photoresist underlayer; and
wherein a second polymer material, included in the photoresist underlayer, comprises:
a second main polymer chain;
a crosslinking group component; and
a plurality of polar groups.

17. The method of claim 15, wherein the photoresist underlayer comprises a co-polymer material that comprises:
the main polymer chain;
the plurality of acid generator component side chains;
the acid generator component;
a crosslinking group component; and
a plurality of polar groups.

18. The method of claim 17, wherein the main polymer chain is a first main polymer chain included in the photoresist underlayer;
wherein the plurality of acid generator component side chains is a first plurality of acid generator component side chains included in the photoresist underlayer;
wherein the acid generator component is a first acid generator component included in the photoresist underlayer; and
wherein a polymer material, included in the photoresist underlayer, comprises:
a second main polymer chain;
a second plurality of acid generator component side chains coupled with the second main polymer chain; and
a second acid generator component coupled with the second plurality of acid generator component side chains.

19. The method of claim 17, wherein the main polymer chain is a first main polymer chain included in the photoresist underlayer;
wherein the crosslinking group component is a first crosslinking group component included in the photoresist underlayer;
wherein the plurality of polar groups is a first plurality of polar groups included in the photoresist underlayer; and
wherein a polymer material, included in the photoresist underlayer, comprises:
a second main polymer chain;
a second crosslinking group component; and
a second plurality of polar groups.

20. The method of claim 17, wherein the main polymer chain is a first main polymer chain included in the photoresist underlayer;
wherein the plurality of acid generator component side chains is a first plurality of acid generator component side chains included in the photoresist underlayer;
wherein the acid generator component is a first acid generator component included in the photoresist underlayer;
wherein the crosslinking group component is a first crosslinking group component included in the photoresist underlayer;
wherein the plurality of polar groups is a first plurality of polar groups included in the photoresist underlayer;
wherein a first polymer material, included in the photoresist underlayer, comprises:
a second main polymer chain;
a second crosslinking group component; and
a second plurality of polar groups; and
wherein a second polymer material, included in the photoresist underlayer, comprises:
a third main polymer chain;
a second plurality of acid generator component side chains coupled with the third main polymer chain; and
a second acid generator component coupled with the second plurality of acid generator component side chains.
